(19) United States
(12) Patent Application Publication
(10) Pub. No.: US 2026/0237421 A1
(43) Pub. Date: Aug. 13, 2026

(54) Reporting a Notification-Type Event

(71) Applicant: Micron Technology, Inc., Boise, ID (US)

(72) Inventors: Yang Lu, Boise, ID (US); Matthew A. Prather, Boise, ID (US); Gary Lynn Howe, Allen, TX (US); Kang-Yong Kim, Boise, ID (US)

(73) Assignee: Micron Technology, Inc., Boise, ID (US)

(21) Appl. No.: 19/050,425

(22) Filed: Feb. 11, 2025

(51) Int. Cl. G06F 11/07; G06F 11/10

(52) U.S. Cl. CPC G11C 11/4078; G06F 11/0793; G06F 11/1068; G11C 11/406

(57) ABSTRACT

Apparatuses and techniques for reporting a notification-type event are described. In an example aspect, a memory device includes a dedicated notification pin for reporting one or more notification-type events to a memory controller. Through the notification pin, the memory device can indicate an occurrence of various notification-type events, one or more of which can be associated with mitigating usage-based disturbance. In contrast to an alert pin, the notification pin enables an operation of the memory controller to continue uninterrupted. In other words, notification-type events that are reported via the notification pin do not need to interrupt an operation of the memory controller. In this way, the notification pin can be used to communicate notifications without degrading performance of the memory controller. Also, with a dedicated notification pin, the memory controller can avoid continuously polling mode registers of the memory device for information, thereby conserving power and temporal resources.

### BACKGROUND

Computers, smartphones, and other electronic devices rely on processors and memories. A processor executes code based on data to run applications and provide features to a user. The processor obtains the code and the data from a memory. The memory in an electronic device can include volatile memory (e.g., random-access memory (RAM)) and non-volatile memory (e.g., flash memory). Like the capabilities of a processor, the capabilities of a memory can impact the performance of an electronic device. This performance impact can increase as processors are developed that execute code faster and as applications operate on increasingly larger data sets that require ever-larger memories.

### BRIEF DESCRIPTION OF THE DRAWINGS

Apparatuses and techniques for reporting a notification-type event are described with reference to the following drawings. The same numbers are used throughout the drawings to reference like features and components:

FIG. 1 illustrates example apparatuses that can implement aspects of reporting a notification-type event;

FIG. 2 illustrates an example computing system that can implement aspects of reporting a notification-type event;

FIG. 3 illustrates example data stored within rows of a memory array;

FIG. 4 illustrates an example memory device in which aspects of reporting a notification-type event can be implemented;

FIG. 5 illustrates an example arrangement of circuits that can implement aspects of reporting a notification-type event;

FIG. 6 illustrates an example memory device coupled to an interface that supports reporting of a notification-type event;

FIG. 7 illustrates example notification-type events and example alert-type events;

FIG. 8 illustrates an example timing diagram for reporting multiple notification-type events;

FIG. 9 illustrates an example implementation of an event reporting circuit for reporting a notification-type event;

FIG. 10 illustrates an example implementation of a notification pin;

FIG. 11 illustrates an example scheme performed by an event reporting circuit for reporting different types of events;

FIG. 12 illustrates an example method performed by a memory device for reporting a notification-type event; and

FIG. 13 illustrates an example method performed by a memory controller for receiving a report of a notification-type event.

### DETAILED DESCRIPTION

### Overview

Processors and memory work in tandem to provide features to users of computers and other electronic devices. As processors and memory operate more quickly together in a complementary manner, an electronic device can provide enhanced features, such as high-resolution graphics and artificial intelligence (AI) analysis. Some applications, such as those for financial services, medical devices, and advanced driver assistance systems (ADAS), can also demand more-reliable memories. These applications use increasingly reliable memories to limit errors in financial transactions, medical decisions, and object identification, respectively. In some implementations, however, more-reliable memories can sacrifice bit density, power efficiency, and simplicity.

To meet the demands for physically smaller memories, memory devices can be designed with higher chip densities for the memory cells. Increasing chip density, however, can increase the electromagnetic coupling between proximate rows of memory cells due, at least in part, to a shrinking distance between these rows. With this undesired electromagnetic coupling (e.g., capacitive coupling), activation (or charging) of a first row of memory cells can sometimes negatively impact the integrity of the digital values stored in a second nearby row of memory cells. This phenomenon is referred to as usage-based disturbance herein. Activation of the first row can generate interference, or crosstalk, that causes the second row to experience a voltage fluctuation. In some instances, this voltage fluctuation can cause a state, or value, of a memory cell in the second row to be incorrectly determined by a sense amplifier. Consider an example in which a state of a memory cell in the second row is a logical “1” (e.g., a high voltage). In this example, the voltage fluctuation can cause a sense amplifier to incorrectly determine the state of the memory cell to be a logical “0” (e.g., a low voltage) instead of a logical “1.” Left unchecked, this interference can lead to memory errors or data loss within the memory device.

In some circumstances, a particular row of memory cells is activated repeatedly in an unintentional or intentional manner, which can be part of a malicious act. Such a row that is repeatedly activated is referred to herein as an aggressor row. Consider, for instance, that memory cells in an R^{th} row are subjected to repeated activation, which causes one or more memory cells in a proximate row (e.g., an adjacent row) to change states. Here, a proximate row can include another row within an R+1 row, which is an adjacent row; an R+2 row; an R−1 row, which is another adjacent row; and/or an R−2 row. These proximate rows are referred to herein as victim rows. The effect of changed memory states is referred to as a usage-based disturbance. The occurrence of usage-based disturbance can lead to the corruption or changing of contents within the affected row of memory. As described herein below, to combat the negative effects of usage-based disturbance, a memory device can perform usage-based-disturbance mitigation operations.

Some memory devices utilize circuits that can detect usage-based disturbance and mitigate its effects. To monitor for usage-based disturbance, a memory device can store an activation count for each row of a memory array. The activation count keeps track of a quantity of accesses or activations of the corresponding memory row. If the activation count meets (e.g., equals or exceeds) a threshold, nearby rows may be at increased risk for data corruption due to the repeated activations of the accessed row and the usage-based disturbance effect. To manage this risk to the affected rows, the memory device can refresh the proximate rows.

Mitigating usage-based disturbance can be a challenging balancing act in the presence of limited resources. It is generally desirable for the memory device to perform refresh operations to reduce a probability that the usage-based disturbance effect will manifest a data error. Refresh operations, however, consume power and limit an availability of the memory device to perform other operations, including normal read and write operations, thereby degrading an overall performance of the memory device as more refresh operations are performed.

Although limiting refresh operations for usage-based-disturbance mitigation can improve the overall performance and the power efficiency of the memory device, there is a greater risk of activation counts of one or more rows reaching an intrinsic specified limitation. To prevent this from happening, the memory device can become inaccessible to a memory controller and the user while it addresses an alert condition. As this denial-of-service (DOS) situation may be unsatisfactory for some host devices and/or users, memory controllers may be designed to overservice refresh operations for usage-based-disturbance mitigation at the cost of decreasing the overall performance and the power efficiency of the memory device.

Some memory devices do not communicate, to a memory controller, information regarding operations for mitigating usage-based disturbance until an alert condition causes a denial-of-service situation to occur. With limited visibility into the memory device's operations, it can be challenging for the memory controller to evaluate whether the current scheduling of refresh commands is appropriate. If the memory controller sends too many refresh commands, it is overservicing the usage-based-disturbance-mitigation operations and thereby wasting power and temporal resources that could otherwise be available for servicing memory requests for program execution. However, if the memory controller sends too few refresh commands, there is a higher risk of a denial-of-service situation occurring. In the case that the memory device does not provide an indication of its status regarding mitigating usage-based disturbance, the memory controller is unable to make changes in its scheduling of refresh commands to better balance overall performance and power efficiency with mitigating usage-based disturbance and preventing the denial-of-service situation.

To address this problem, some memory devices may communicate status information to a memory controller via one or more mode registers. The memory controller, however, has to periodically read these mode registers to obtain the information. These read operations consume time and waste power resources, especially during situations in which there is no new information stored in the mode registers.

Other memory devices can communicate this information via an alert pin. Passing signals carrying information associated with non-alert-type conditions and alert-type conditions via a same alert pin, however, can make it challenging for the memory controller to appropriately interpret the various signals. If the memory controller is not implemented with additional logic to distinguish between these types of signals, the signals carrying information associated with the non-alert-type conditions can force an interrupt, which causes the memory controller to halt its current operation to address the non-alert-type condition. This interruption wastes temporal resources of the memory controller, thereby decreasing its overall performance. There is a general need to communicate non-alert-type information to a memory controller in a power-efficient manner that does not degrade performance.

To address this challenge, this document describes techniques for reporting a notification-type event. In an example aspect, a memory device includes a dedicated notification pin for reporting one or more notification-type events to a memory controller. Through the notification pin, the memory device can indicate occurrences of various notification-type events, one or more of which can be associated with mitigating usage-based disturbance. In contrast to an alert pin, the notification pin enables an operation of the memory controller to continue uninterrupted even if the memory device asserts the notification pin. In other words, notification-type events that are reported via the notification pin do not necessarily or automatically interrupt an operation of the memory controller. In this way, the notification pin does not degrade the performance of the memory controller with unnecessary interruptions. Also, with a dedicated notification pin, the memory controller can avoid continuously polling mode registers of the memory device for information, thereby conserving power and temporal resources that can otherwise be used to service memory requests for program execution.

### Example Operating Environments

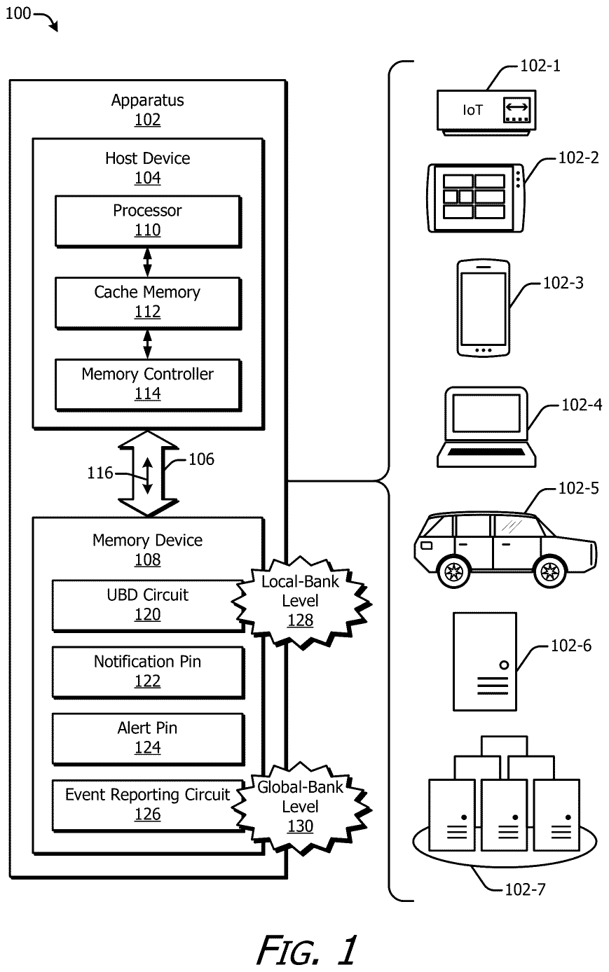

FIG. 1 illustrates, at 100 generally, an example operating environment including an apparatus 102 that can perform aspects of reporting multiple events associated with mitigating usage-based disturbance. The apparatus 102 can include various types of electronic devices, including an internet-of-things (IoT) device 102-1, tablet device 102-2, smartphone 102-3, notebook computer 102-4, passenger vehicle 102-5, server computer 102-6, and server cluster 102-7 that may be part of cloud computing infrastructure, a data center, or a portion thereof (e.g., a printed circuit board (PCB)). Other examples of the apparatus 102 include a wearable device (e.g., a smartwatch or intelligent glasses), entertainment device (e.g., a set-top box, video dongle, smart television, a gaming device), desktop computer, motherboard, server blade, consumer appliance, vehicle, drone, industrial equipment, security device, sensor, or the electronic components thereof. Each type of apparatus can include one or more components to provide computing functionalities or features.

In example implementations, the apparatus 102 can include at least one host device 104, at least one interconnect 106, and at least one memory device 108. The host device 104 can include at least one processor 110, at least one cache memory 112, and a memory controller 114. The memory device 108, which can also be realized with a memory module, can include, for example, a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory for the apparatus 102. Although not illustrated, the apparatus 102 can also include storage memory. The storage memory can include, for example, a storage-class memory device (e.g., a flash memory, hard disk drive, solid-state drive, phase-change memory (PCM), or memory employing 3D XPoint™).

The processor 110 is operatively coupled to the cache memory 112, which is operatively coupled to the memory controller 114. The processor 110 is also coupled, directly or indirectly, to the memory controller 114. The host device 104 may include other components to form, for instance, a system-on-a-chip (SoC). The processor 110 may include a general-purpose processor, central processing unit, graphics processing unit (GPU), neural network engine or accelerator, application-specific integrated circuit (ASIC), field-programmable gate array (FPGA) integrated circuit (IC), or communications processor (e.g., a modem or baseband processor).

In operation, the memory controller 114 can provide a high-level or logical interface between the processor 110 and at least one memory (e.g., an external memory). The memory controller 114 may be realized with any of a variety of suitable memory controllers (e.g., a double-data-rate (DDR) memory controller that can process requests for data stored on the memory device 108). Although not shown, the host device 104 may include a physical interface (PHY) that transfers data between the memory controller 114 and the memory device 108 through the interconnect 106. For example, the physical interface may be an interface that is compatible with a DDR PHY Interface (DFI) Group interface protocol. The memory controller 114 can, for example, receive memory requests from the processor 110 and provide the memory requests to external memory with appropriate formatting, timing, and reordering. The memory controller 114 can also forward to the processor 110 responses to the memory requests received from external memory.

The host device 104 is operatively coupled, via the interconnect 106, to the memory device 108. In some examples, the memory device 108 is connected to the host device 104 via the interconnect 106 with an intervening buffer or cache. The memory device 108 may operatively couple to storage memory (not shown). The host device 104 can also be coupled, directly or indirectly via the interconnect 106, to the memory device 108 and the storage memory. The interconnect 106 and other interconnects (not illustrated in FIG. 1) can transfer data between two or more components of the apparatus 102. Examples of the interconnect 106 include a bus (e.g., a unidirectional or bidirectional bus), switching fabric, or one or more wires that carry voltage or current signals. The interconnect 106 can propagate one or more communications 116 between the host device 104 and the memory device 108. For example, the host device 104 may transmit a memory request to the memory device 108 over the interconnect 106. Also, the memory device 108 may transmit a corresponding memory response to the host device 104 over the interconnect 106.

The illustrated components of the apparatus 102 represent an example architecture with a hierarchical memory system. A hierarchical memory system may include memories at different levels, with each level having memory with a different speed or capacity. As illustrated, the cache memory 112 logically couples the processor 110 to the memory device 108. In the illustrated implementation, the cache memory 112 is at a higher level than the memory device 108. A storage memory, in turn, can be at a lower level than the main memory (e.g., the memory device 108). Memory at lower hierarchical levels may have a decreased speed but increased capacity relative to memory at higher hierarchical levels.

The apparatus 102 can be implemented in various manners with more, fewer, or different components. For example, the host device 104 may include multiple cache memories (e.g., including multiple levels of cache memory) or no cache memory. In other implementations, the host device 104 may omit the processor 110 or the memory controller 114. A memory (e.g., the memory device 108) may have an “internal” or “local” cache memory. As another example, the apparatus 102 may include cache memory between the interconnect 106 and the memory device 108. Computer engineers can also include any of the illustrated components in distributed or shared memory systems.

Computer engineers may implement the host device 104 and the various memories in multiple manners. In some cases, the host device 104 and the memory device 108 can be disposed on, or physically supported by, a printed circuit board (e.g., a rigid or flexible motherboard). The host device 104 and the memory device 108 may additionally be integrated together on an integrated circuit or fabricated on separate integrated circuits and packaged together. The memory device 108 may also be coupled to multiple host devices 104 via one or more interconnects 106 and may respond to memory requests from two or more host devices 104. Each host device 104 may include a respective memory controller 114, or the multiple host devices 104 may share a memory controller 114. This document describes with reference to FIG. 1 an example computing system architecture having at least one host device 104 coupled to a memory device 108.

Two or more memory components (e.g., modules, dies, banks, or bank groups) can share the electrical paths or couplings of the interconnect 106. The interconnect 106 can include at least one command-and-address bus (CA bus) and at least one data bus (DQ bus). The command-and-address bus can transmit addresses and commands from the memory controller 114 of the host device 104 to the memory device 108, which may exclude propagation of data. The data bus can propagate data between the memory controller 114 and the memory device 108. The memory device 108 may also be implemented as any suitable memory including, but not limited to, DRAM, SDRAM, three-dimensional (3D) stacked DRAM, DDR memory, or LPDDR memory (e.g., LPDDR DRAM or LPDDR SDRAM).

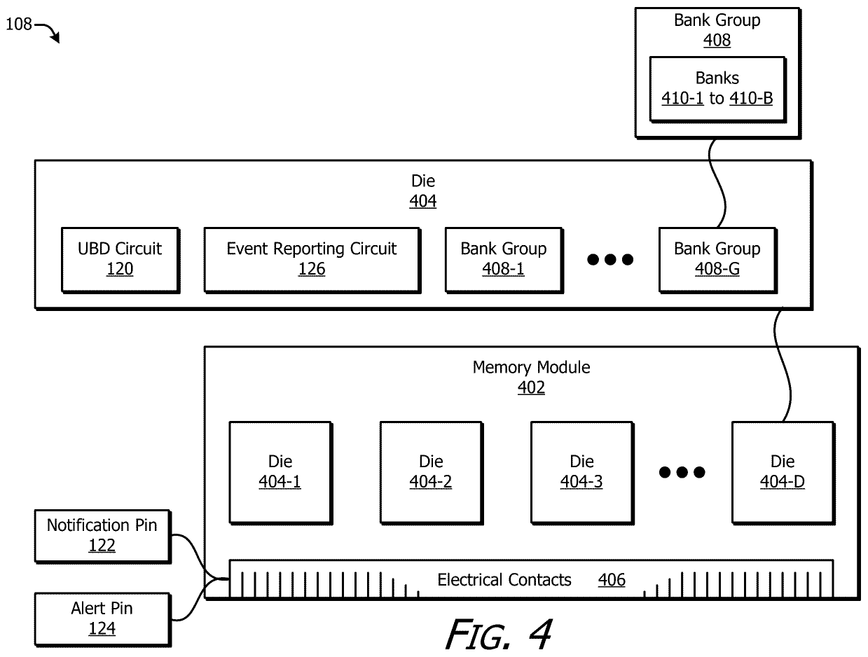

The memory device 108 can form at least part of the main memory of the apparatus 102. The memory device 108 may, however, form at least part of a cache memory, a storage memory, or a system-on-chip of the apparatus 102. The memory device 108 includes at least one usage-based-disturbance circuit 120 (UBD circuit 120). The usage-based-disturbance circuit 120 mitigates usage-based disturbance for one or more banks associated with the memory device 108, as further described with respect to FIGS. 4 to 6. This includes detecting a condition associated with usage-based disturbance and refreshing one or more victim rows associated with the detected condition.

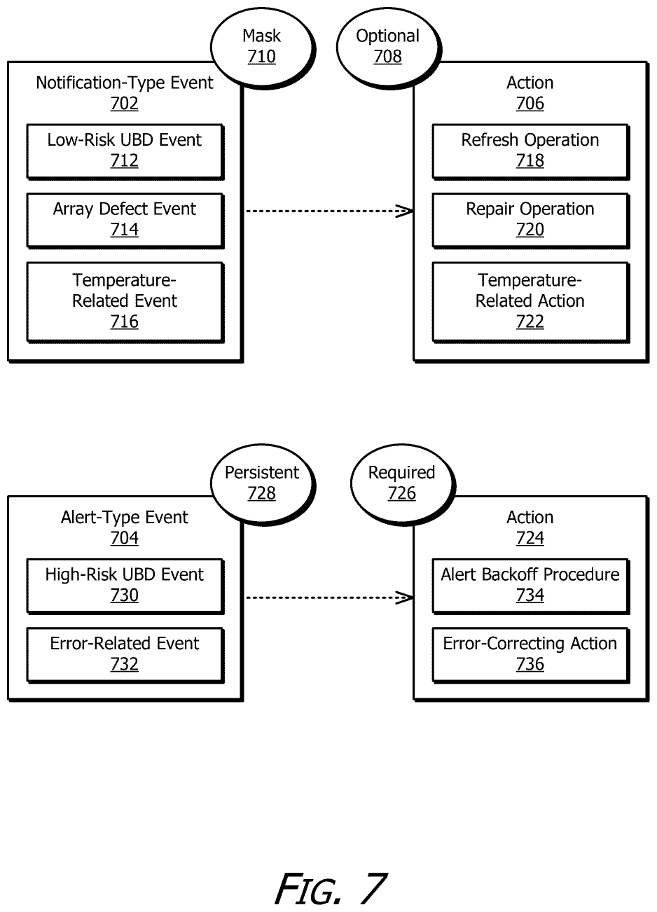

The memory device 108 also includes at least one notification pin 122 and at least one alert pin 124. The notification pin 122 and the alert pin 124 couple the memory device 108 to the memory controller 114, such as through the interconnect 106. The memory device 108 can report an occurrence of a notification-type event via the notification pin 122. In general, notification-type events have a lower risk of triggering an alert condition if the memory controller 114 does not take immediate action (e.g., does not send more refresh commands in the case of usage-based-disturbance mitigation). As such, notification-type events that are reported via the notification pin 122 enable an operation of the memory controller 114 to continue uninterrupted. In other words, the operation of the memory controller 114 is not necessarily or automatically interrupted by the reporting of a notification-type event. For example, the memory controller 114 is not obligated to react immediately to the reporting of a notification-type event. Instead, the memory controller 114 can decide to act based on the reporting of the notification-type event at a later time to reduce the impact to performance. Some notification-type events can be associated with usage-based-disturbance mitigation while other notification-type events can be associated with normal operations (e.g., other operations that do not involve mitigating usage-based disturbance), as further described with respect to FIG. 7.

The memory device 108 can report an occurrence of an alert-type event via the alert pin 124. In general, alert-type events have a higher risk of triggering an alert condition if the memory controller 114 does not take action (e.g., does not send more refresh commands in the case of usage-based-disturbance mitigation). As such, alert-type events that are reported via the alert pin 124 halt or interrupt the operation of the memory controller 114 (e.g., normal operations of the memory controller 114 related to making read and write requests). Some alert-type events can be associated with usage-based-disturbance mitigation while other alert-type events can be associated with normal operations, as further described with respect to FIG. 7.

The memory device 108 also includes at least one event reporting circuit 126. The event reporting circuit 126 performs aspects of reporting notification-type events via the notification pin 122. Depending on the implementation, the event reporting circuit 126 can also detect an occurrence of one or more notification-type events. The type or kind of notification-type events that are reported by the event reporting circuit 126 can at least include events associated with mitigating usage-based disturbance. Optionally, the event reporting circuit 126 can report other types or kinds of notification-type events, including those associated with normal operations.

In some implementations, the event reporting circuit 126 can report alert-type events via the alert pin 124. In other implementations, the reporting of alert-type events can be performed by a different circuit that is separate and/or independent from the event reporting circuit 126. The usage-based-disturbance circuit 120 and the event reporting circuit 126 can each be implemented using software, firmware, hardware, fixed logic circuitry, or some combinations thereof. By reporting notification-type events and alert-type events via different pins 122 and 124, the memory device 108 can make it easier for the memory controller 114 to take appropriate action and efficiently manage available resources in a power-efficient and performance-preserving manner.

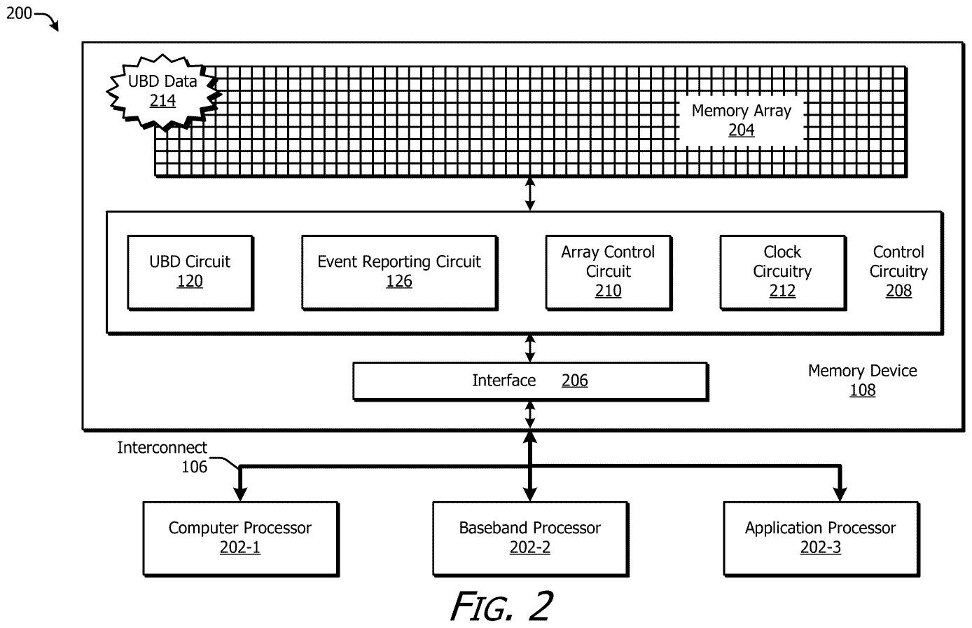

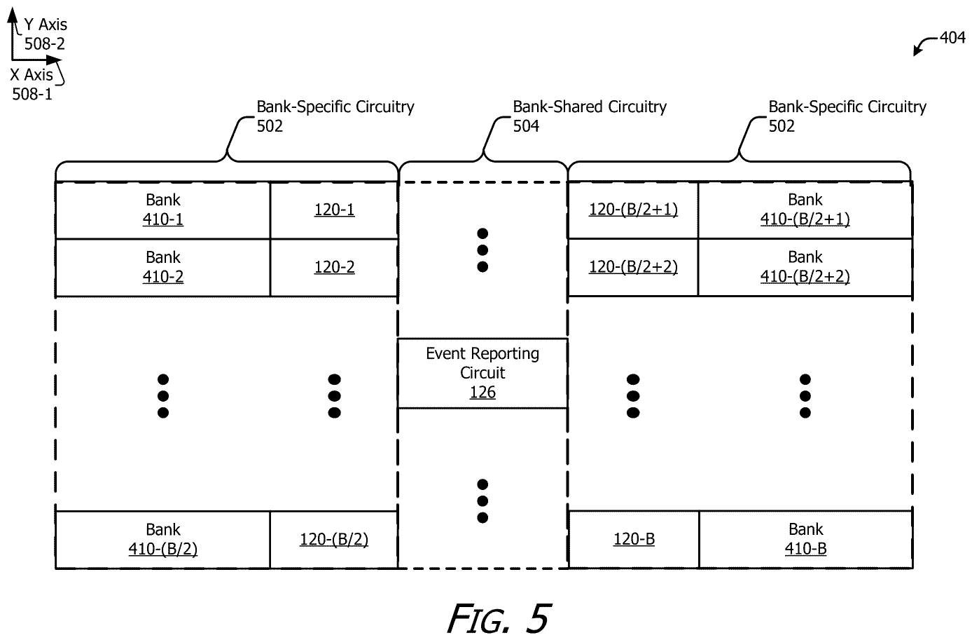

In example implementations, the usage-based-disturbance circuit 120 is implemented at a local-bank level 128 (or a local level). This means that each instance of the usage-based-disturbance circuit 120 is associated with a particular bank or a particular set of banks. In contrast, the event reporting circuit 126 is implemented at a global-bank level 130 (e.g., a global level or a central level). This means that one instance of the event reporting circuit 128 implemented at the global-bank level 130 can interface with two or more usage-based-disturbance circuits 120 that are implemented at the local-bank level 128. The relationship between the local-bank level 128 and the global-bank level 130 is further described with respect to FIG. 5. Other components of the memory device 108 are further described with respect to FIG. 2.

FIG. 2 illustrates an example computing system 200 that can implement aspects of reporting a notification-type event. In some implementations, the computing system 200 includes at least one memory device 108, at least one interconnect 106, and at least one processor 202. The memory device 108 can include, or be associated with, at least one memory array 204, at least one interface 206, and control circuitry 208 (or periphery circuitry) operatively coupled to the memory array 204. The memory array 204 can include an array of memory cells, including but not limited to memory cells of DRAM, SDRAM, three-dimensional (3D) stacked DRAM, DDR memory, LPDDR SDRAM, and so forth. The memory array 204 and the control circuitry 208 may be components on a single semiconductor die or on separate semiconductor dies. The memory array 204 or the control circuitry 208 may also be distributed across multiple dies. This control circuitry 208 may manage traffic on a bus that is separate from the interconnect 106.

The control circuitry 208 can include various components that the memory device 108 can use to perform various operations. These operations can include communicating with other devices, managing memory performance, performing refresh operations (e.g., self-refresh operations or auto-refresh operations), and performing memory read or write operations. In the depicted configuration, the control circuitry 208 includes the usage-based-disturbance circuit 120, the event reporting circuit 126, at least one array control circuit 210, and at least one instance of clock circuitry 212. In some implementations, the usage-based-disturbance circuit 120 and the event reporting circuit 126 are part of the control circuitry 208, as shown in FIG. 2. In other implementations, the usage-based-disturbance circuit 120 and/or the event reporting circuit 126 are considered separate from the control circuitry 208.

The array control circuit 210 can include circuitry that provides command decoding, address decoding, input/output functions, amplification circuitry, power supply management, power control modes, and other functions. The clock circuitry 212 can synchronize various memory components with one or more external clock signals provided over the interconnect 106, including a command-and-address clock or a data clock. The clock circuitry 212 can also use an internal clock signal to synchronize memory components and may provide timer functionality.

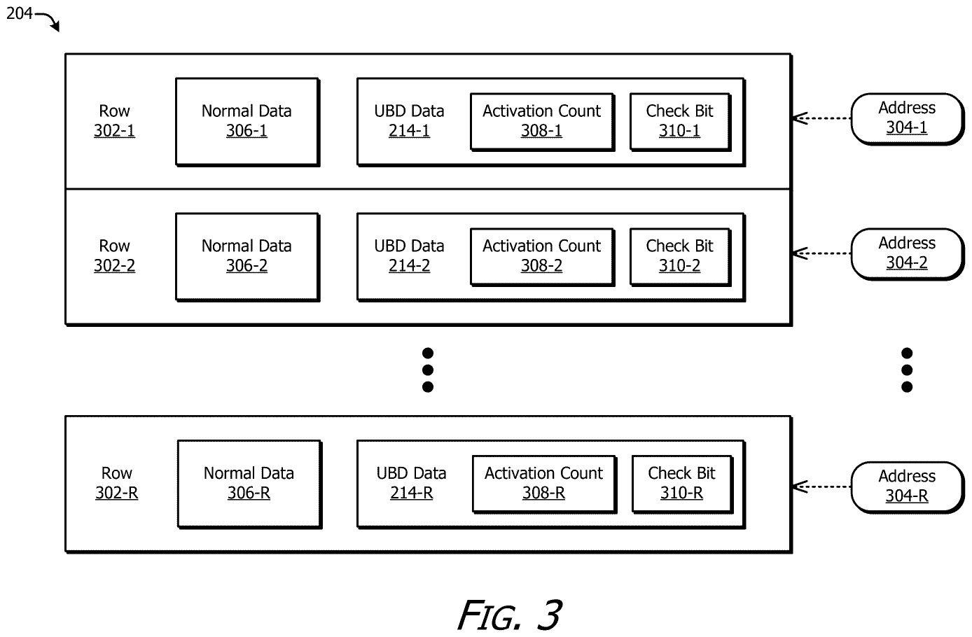

The usage-based-disturbance circuit 120 can be coupled to a set of memory cells within the memory array 204 that store usage-based-disturbance data 214 (UBD data 214). The usage-based-disturbance data 214 can include information such as an activation count, which represents a quantity of times one or more rows within the memory array 204 have been activated (or accessed) by the memory device 108. In example implementations, each row of the memory array 204 includes a subset of memory cells that stores the usage-based-disturbance data 214 associated with that row, as further described with respect to FIG. 3.

The interface 206 can couple the control circuitry 208 or the memory array 204 directly or indirectly to the interconnect 106. Although not explicitly shown in FIG. 2, the interface 206 can include the notification pin 122 and the alert pin 124. In some implementations, the usage-based-disturbance circuit 120, the event reporting circuit 126, the array control circuit 210, and the clock circuitry 212 can be part of a single component (e.g., the control circuitry 208). In other implementations, one or more of the usage-based-disturbance circuit 120, the event reporting circuit 126, the array control circuit 210, or the clock circuitry 212 may be implemented as separate components, which can be provided on a single semiconductor die or disposed across multiple semiconductor dies. These components may individually or jointly couple to the interconnect 106 via the interface 206.

The interconnect 106 may use one or more of a variety of interconnects that communicatively couple together various components and enable commands, addresses, or other information and data to be transferred between two or more components (e.g., between the memory device 108 and the processor 202). Although the interconnect 106 is illustrated with a single line in FIG. 2, the interconnect 106 may include at least one bus, at least one switching fabric, one or more wires or traces that carry voltage or current signals, at least one switch, one or more buffers, and so forth. Further, the interconnect 106 may be separated into at least a command-and-address bus and a data bus.

In some aspects, the memory device 108 may be a “separate” component relative to the host device 104 (of FIG. 1) or any of the processors 202. The separate components can include a printed circuit board, memory card, memory stick, and memory module (e.g., a single in-line memory module (SIMM) or dual in-line memory module (DIMM)). Thus, separate physical components may be located together within the same housing of an electronic device or may be distributed over a server rack, a data center, and so forth. Alternatively, the memory device 108 may be integrated with other physical components, including the host device 104 or the processor 202, by being combined on a printed circuit board or in a single package or a system-on-chip.

As shown in FIG. 2, the processors 202 may include a computer processor 202-1, a baseband processor 202-2, and an application processor 202-3, coupled to the memory device 108 through the interconnect 106. The processors 202 may include or form a part of a central processing unit, graphics processing unit, system-on-chip, application-specific integrated circuit, or field-programmable gate array. In some cases, a single processor can comprise multiple processing resources, each dedicated to different functions (e.g., modem management, applications, graphics, central processing). In some implementations, the baseband processor 202-2 may include or be coupled to a modem (not illustrated in FIG. 2) and referred to as a modem processor. The modem or the baseband processor 202-2 may be coupled wirelessly to a network via, for example, cellular, Wi-Fi™, Bluetooth™, near field, or another technology or protocol for wireless communication.

In some implementations, the processors 202 may be connected directly to the memory device 108 (e.g., via the interconnect 106). In other implementations, one or more of the processors 202 may be indirectly connected to the memory device 108 (e.g., over a network connection or through one or more other devices). The memory array 204 is further described with respect to FIG. 3.

FIG. 3 illustrates example data stored within rows of the memory array 204. The memory array 204 includes multiple rows 302 of memory cells. For example, the memory array 204 depicted in FIG. 3 includes rows 302-1, 302-2 . . . 302-R, where R represents a positive integer. Each row 302 is associated with an address 304 (e.g., a row address, a memory row address, or a memory address). For example, the first row 302-1 has a first address 304-1, the second row 302-2 has a second address 304-2, and an R^{th} row 302-R has an R^{th} address 304-R.

Each of the rows 302 can store normal data 306 within a first subset of the memory cells associated with that row 302. The normal data 306 represents data that is read from or written to the memory device 108 during normal memory operations (e.g., during normal read or write operations). The normal data 306, for example, can include data that is transmitted by the memory controller 114 and is written to one or more rows 302 of the memory array 204.

In addition to the normal data 306, each of the rows 302 can store usage-based-disturbance data 214 within a second subset of the memory cells associated with that row 302. The usage-based-disturbance data 214 includes information that enables the usage-based-disturbance circuit 120 to mitigate usage-based disturbance. In an example implementation, the usage-based-disturbance data 214 includes an activation count 308. With the activation count 308, the memory device 108 can keep track of a quantity of accesses or activations of the corresponding memory row 302. In some example implementations, the usage-based-disturbance data 214 can also include a count of how many times a neighboring row (e.g., an adjacent or a proximate row) is refreshed in order to mitigate usage-based disturbance. Each of these counts provide an example means by which the memory device 108 can monitor for usage-based disturbance and determine when to refresh victim rows to reduce the risk of usage-based disturbance corrupting data.

In the example shown in FIG. 3, the first row 302-1 stores first normal data 306-1 within a first subset of memory cells of the first row 302-1 and stores first usage-based-disturbance data 214-1 within a second subset of memory cells of the first row 302-1. The first usage-based-disturbance data 214-1 includes a first activation count 308-1, which represents a quantity of times the first row 302-1 has been activated since a last refresh. As another example, the second row 302-2 stores second normal data 306-2 within a first subset of memory cells within the second row 302-2 and stores second usage-based-disturbance data 214-2 within a second subset of memory cells within the second row 302-2. The second usage-based-disturbance data 214-2 includes a second activation count 308-2, which represents a quantity of times the second row 302-2 has been activated since a last refresh. Additionally, the R^{th} row 302-R stores R^{th} normal data 306-R within a first subset of memory cells within the R^{th} row 302-R and stores R^{th} usage-based-disturbance data 214-R within a second subset of memory cells within the R^{th} row 302-R. The R^{th} usage-based-disturbance data 214-R includes an R^{th} activation count 308-R, which represents a quantity of times the R^{th} row 302-R has been activated since a last refresh.

The usage-based-disturbance data 214 can also include information or can be formatted (e.g., coded) in such a way as to support error detection. In this example, the usage-based-disturbance data 214 includes a check bit 310, such as a parity check bit or error-correcting-code check bits. In particular, the usage-based-disturbance data 214-1, 214-2, and 214-R respectively include check bits 310-1, 310-2, and 310-R. Other implementations are also possible in which the usage-based-disturbance data 214 is coded in a manner that supports any of the error detection tests described above, such as the error-correcting-code check. Although the techniques for detecting a condition associated with usage-based disturbance is generally described with respect to the activation count 308, these techniques can generally be applied to detecting a condition based on any type of information that is represented by the usage-based-disturbance data 214, including error detection techniques.

### Example Techniques and Hardware

FIG. 4 illustrates an example memory device 108 in which aspects of reporting multiple events associated with mitigating usage-based disturbance can be implemented. The memory device 108 includes a memory module 402, which can include multiple dies 404. As illustrated, the memory module 402 includes a first die 404-1, a second die 404-2, a third die 404-3, and a D^{th} die 404-D, with D representing a positive integer. The memory module 402 can be a SIMM or a DIMM. As another example, the memory module 402 can interface with other components via a bus interconnect (e.g., a Peripheral Component Interconnect Express (PCIe®) bus). The memory device 108 illustrated in FIGS. 1 and 2 can correspond, for example, to multiple dies (or dice) 404-1 through 404-D, or a memory module 402 with two or more dies 404. As shown, the memory module 402 can include one or more electrical contacts 406 (e.g., pins) to interface the memory module 402 to other components.

The electrical contacts 406 can include the notification pin 122 and the alert pin 124. Each die 404 may include a respective notification pin 122 and alert pin 124. Additionally or alternatively, each package (not shown), which can include multiple dies, may have a respective notification pin 122 and alert pin 124. In various implementations, the memory device 108 can include multiple notification pins 122, which are connected together at a package level and/or at a module level.

In an example implementation, each memory module 402 includes a single notification pin 122 and a single alert pin 124. In another example implementation, each memory module 402 includes multiple pairs of notification pins 122 and alert pins 124. In this case, each pair of pins corresponds to a die 404 of the memory module 402. In still other implementations, the memory device 108 can include a single pin (e.g., a single notification pin 122 and/or a single alert pin 124) for each rank or for each package. Multiple notification pins 122 and/or multiple alert pins 124 can be connected together by a communication bus. In general, this communication bus is unlikely to be a high traffic bus, which means there is not a high probability of conflicts occurring on the communication bus.

A type and/or configuration of the notification pin 122 can be similar or different to the alert pin 124. Generally speaking, the notification pin 122 and the alert pin 124 can be implemented using any type of pin or using any configuration of pin. In an example implementation, the notification pin 122 and/or the alert pin 124 are implemented as open-drain pull-down pins. Implementing the notification pin 122 and the alert pin 124 using a same type and configuration can simplify a design of the memory device 108.

The memory module 402 can be implemented in various manners. For example, the memory module 402 may include a printed circuit board, and the multiple dies 404-1 through 404-D may be mounted or otherwise attached to the printed circuit board. The dies 404 (e.g., memory dies) may be arranged in a line or along two or more dimensions (e.g., forming a grid or array). The dies 404 may have a similar size or may have different sizes. Each die 404 may be similar to another die 404 or different in size, shape, data capacity, or control circuitries. The dies 404 may also be positioned on a single side or on multiple sides of the memory module 402.

One or more of the dies 404-1 to 404-D include the usage-based-disturbance circuit 120, the event reporting circuit 126, and bank groups 408-1 to 408-G, with G representing a positive integer. Each bank group 408 includes at least two banks 410, such as banks 410-1 to 410-B, with B representing a positive integer. In some implementations, the die 404 includes multiple instances of the usage-based-disturbance circuit 120, which mitigate usage-based disturbance across at least one of the banks 410. For example, multiple instances of the usage-based-disturbance circuit 120 can respectively mitigate usage-based disturbance across the bank groups 408-1 to 408-G.

In other implementations, multiple instances of the usage-based-disturbance circuit 120 can respectively mitigate usage-based disturbance for respective banks 410. In this case, each usage-based-disturbance circuit 120 mitigates usage-based disturbance for a single bank 410 within one of the bank groups 408-1 to 408-B. In yet other example implementations, each usage-based-disturbance circuit 120 mitigates usage-based disturbance for a subset of the banks 410 associated with one of the bank groups 408-1 to 408-G, where the subset of the banks 410 includes at least two banks 410.

Various implementations of the event reporting circuit 126 are also possible. In a first example, the die 404 includes a single event reporting circuit 126 that is coupled to the one or more instances of the usage-based-disturbance circuit 120. In a second example, the die 404 includes multiple event reporting circuit 126 that are coupled to respective sets of one or more usage-based-disturbance circuits 120.

The die 404 can include a single instance of the event reporting circuit 126, which is coupled to the one or more instances of the usage-based-disturbance circuit 120. The relationship between the banks 410-1 to 410-B, the usage-based-disturbance circuit 120, and the event reporting circuit 126 are further described with respect to FIG. 5.

FIG. 5 illustrates an example arrangement of multiple instances of the usage-based-disturbance circuit 120 on a die 404. The die 404 includes bank-specific circuitry 502 and bank-shared circuitry 504. Bank-specific circuitry 502 includes components that are associated with a particular bank 410. For example, the bank-specific circuitry 502 includes the banks 410-1, 410-2 . . . 410-(B/2), 410-(B/2+1), 410-(B/2+2) . . . 410-B and the usage-based-disturbance circuits 120-1, 120-2 . . . 120-(B/2), 120-(B/2+1), 120-(B/2+2) . . . 120-B. The usage-based-disturbance circuits 120-1 to 120-B are respectively coupled to the banks 410-1 to 410-B. In some cases, subsets of the banks 410-1 to 410-B are associated with different bank groups 408. In an example implementation, the die 404 includes 32 banks 410 (e.g., B equals 32). The 32 banks 410 form eight bank groups 408 (e.g., G equals 8), with each bank group 408 including four of the banks 410. In other cases, the banks 410-1 to 410-B are associated with a single bank group 408.

The bank-shared circuitry 504 includes components that are associated with multiple banks 410. These components perform operations associated with multiple banks 410. Example components of the bank-shared circuitry 504 include the event reporting circuit 126.

On the die 404, the bank-specific circuitry 502 is positioned on two opposite sides of the bank-shared circuitry 504. Explained another way, the bank-shared circuitry 504 can be centrally positioned on the die 404. As such, the event reporting circuit 126 can be positioned closer to a center of the die 404 compared to the edges of the die 404. Positioning the bank-shared circuitry 504 in the center enables routing between the bank-shared circuitry 504 and the bank-specific circuitry 502 to be simplified.

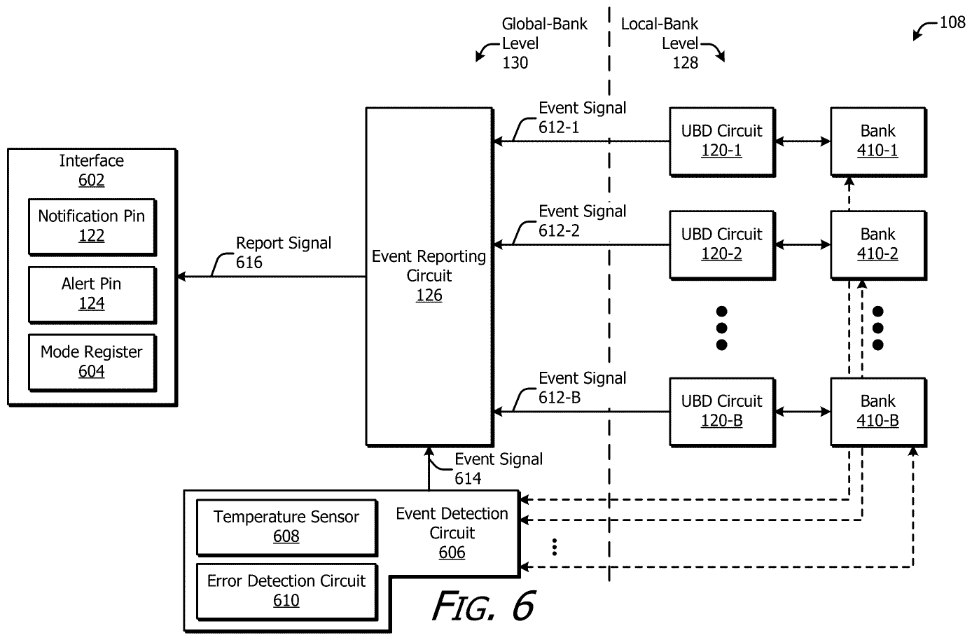

Consider a first axis 508-1 (e.g., X axis 508-1) and a second axis 508-2 (e.g., Y axis 508-2), which is perpendicular to the first axis 508-1. In FIG. 5, the first axis 508-1 is depicted as a “horizontal” axis, and the second axis 508-2 is depicted as a “vertical” axis. Components of the bank-shared circuitry 504 are distributed across the second axis 508-2. A first set of the banks (e.g., banks 410-1 to 410-B/2) are arranged along the second axis 508-2 on a “left” side of the bank-shared circuitry 504, and a second set of the banks (e.g., banks 410-(B/2+1) to 410-B) are arranged along the second axis 508-2 on a “right” side of the bank-shared circuitry 504. The usage-based-disturbance circuits 120-1 to 120-B are positioned between the corresponding banks 410-1 to 410-B and the bank-shared circuitry 504. By positioning the event reporting circuit 126 in a central location between the usage-based-disturbance circuits 120-1 to 120-B, it can be easier to route signals between the event reporting circuit 126 and the usage-based-disturbance circuits 120-1 to 120-B. A relationship between the usage-based-disturbance circuit 120 and the event reporting circuit 126 is further described with respect to FIG. 6.

FIG. 6 illustrates an example memory device 108 capable of reporting a notification-type event. Components of the memory device 108 are depicted with respect to the local-bank level 128, which is illustrated on a right side of FIG. 6, and the global-bank level 130, which is illustrated on a left side of FIG. 6. At the local-bank level 128, the memory device 108 includes the banks 410-1 to 410-B and the usage-based-disturbance circuits 120-1 to 120-B, which are respectively coupled to the banks 410-1 to 410-B.

At the global-bank level 130, the memory device 108 includes the event reporting circuit 126, which is coupled to the usage-based-disturbance circuits 120-1 to 120-B. The event reporting circuit 126 is also coupled to an interface 602, which may or may not be considered part of the memory device 108. The interface 602 can include the interconnect 106 of FIG. 1, the interface 206 of FIG. 2, the electrical contacts 406 of FIG. 4, or some combination thereof. In general, the interface 602 enables the event reporting circuit 126 to communicate with the memory controller 114 (e.g., the host device 104). More specifically, the interface 602 enables the event reporting circuit 126 to report notification-type events to the memory controller 114. In example implementations, the interface 602 can include at least one notification pin 122, at least one mode register 604, at least one communication bus, or some combination thereof. The interface 602 can also include at least one alert pin 124 to enable the event reporting circuit 126 to report alert-type events to the memory controller 114.

The mode register 604 includes at least one operand with one or more event bits that can be set by the event reporting circuit 126. The event bits store additional information about a reported event. The event bits can indicate the type of event that occurred and/or any additional information about the conditions associated with the occurrence of the event. The information stored by the event bits can be used by the memory controller 114 to determine if and/or when it is to take action based on the reporting of a notification-type event. The mode register 604 can be read by the memory controller 114 through a mode register read (MRR) command. In the case of the notification-type event, there can be a delay between a time that the memory device 108 reports an occurrence of an event and a time that the memory controller 114 reads the mode register 604 to receive additional information about the reported event. With the event bits, the mode register 604 can simplify the signaling for reporting multiple notification-type events and/or multiple alert-type events. In some cases, the memory controller 114 can clear the event bits to indicate that it has accessed the information stored in the mode register. This allows new information associated with a next event to be stored in the mode register 604.

In some implementations, the mode register 604 can also include other operands with one or more control bits that enable and/or disable the reporting of notification-type events. Each control bit can be associated with a different notification-type event. The memory controller 114 can set the control bits through a mode register write (MRW) command. The event reporting circuit 126 reads the control bits and selectively reports a detected notification-type event if the corresponding control bit is enabled or skips the reporting of the detected notification-type event if the corresponding control bit is disabled. Using the control bits, the memory controller 114 can dynamically customize which notification-type events can be reported by the memory device 108.

The event reporting circuit 126 can be implemented with or coupled to an event detection circuit 606. The event detection circuit 606 can detect notification-type events and/or alert-type events at the global-bank level 130 (as shown in FIG. 6) or at the local-bank level 128 (not explicitly shown in FIG. 6). In general, the event detection circuit 606 can be an existing circuit within the memory device 108 that performs other functions not associated with usage-based-disturbance mitigation. Example implementations of the event detection circuit 606 can include a temperature sensor 608 and/or an error detection circuit 610.

The temperature sensor 608 measures a temperature associated with a die 404. The temperature sensor 608 can also include other logic to evaluate the measured temperature. For example, the temperature sensor 608 can include at least one comparator to determine if the measured temperature is greater than or equal to a threshold. In another example, the temperature sensor 608 can use one or more comparators to determine if the measured temperature is within an operation range (e.g., within a predetermined temperature range or a specified range).

The error detection circuit 610 can access (e.g., read) the normal data 306 that is stored within the banks 410-1 to 410-B. In example implementations, the error detection circuit 610 can detect and/or correct one or more errors associated with the normal data 306. The error detection circuit 610 can be implemented as a test engine, an error-check and scrub engine (ECS engine), an add-based engine, or a refresh engine.

During operation, the usage-based-disturbance circuits 120 mitigate usage-based disturbance within corresponding banks 410. This includes monitoring for a condition associated with usage-based disturbance, detecting the condition, and initiating a refresh of one or more victim rows associated with the detected condition. To monitor for the condition, the usage-based-disturbance circuit 120 can perform an array counter update (ACU) procedure. As part of the array counter update procedure, the usage-based-disturbance circuit 120 updates (e.g., increments) the activation count 308.

While performing these operations, the usage-based-disturbance circuit 120 can detect an occurrence of an event associated with mitigating usage-based disturbance. The event can represent a status or a state of the memory device 108 for mitigating usage-based disturbance. The type of event can indicate whether the memory device 108 is being given a sufficient quantity of refresh commands from the memory controller 114 or if there is an increased probability of an alert condition occurring. Generally speaking, the usage-based-disturbance circuit 120 can detect a variety of events associated with different risk levels, as further described with respect to FIG. 7.

The usage-based-disturbance circuits 120-1, 120-2, and 120-B respectively generate event signals 612-1, 612-2, and 612-B. With the event signals 612, each usage-based-disturbance circuit 120 can indicate, to the event reporting circuit 126, the detection of an event associated with mitigating usage-based disturbance. In some implementations, the event signals 612 are directly communicated from each of the usage-based-disturbance circuits 120 to the event reporting circuit 126. In other implementations, the event signals 612 can be combined at the local-bank level 128 and a composite event signal can be passed to the event reporting circuit 126 at the global-bank level 130. For some events, additional information about the event can be communicated directly or indirectly from the local-bank level 128 to the global-bank level 130.

For implementations of the memory device 108 that include the event detection circuit 606, the event detection circuit 606 can detect other notification-type events and/or alert-type events that are not associated with mitigating usage-based disturbance. The event detection circuit 606 generates an event signal 614, which can indicate whether or not an event associated with normal operations is detected. For example, the event detection circuit 606 can monitor a temperature of the die 404 using the temperature sensor 608 and generate the event signal 614 to indicate if the measured temperature is greater than or equal to a threshold. As another example, the event detection circuit 606 can monitor for errors within the normal data 306 and generate the event signal 614 to indicate whether an error is present.

The event reporting circuit 126 generates at least one report signal 616 based on the event signals 612 and/or the event signal 614. In some implementations, the event reporting circuit 126 generates different report signals 616 for notification-type events and alert-type events. The report signal 616 can indicate occurrences of multiple notification-type events and/or multiple alert-type events to enable and/or cause the memory controller 114 to take an appropriate action. Example actions are further described with respect to FIG. 7.

The interface 602 passes the report signal 616 (or passes the information carried by the report signal 616) to the memory controller 114 using the notification pin 122 if the report signal 616 is associated with a notification-type event. If the report signal 616 is associated with an alert-type event, the interface 602 passes the report signal 616 (or passes the information carried by the report signal 616) to the memory controller 114 using the alert pin 124. The mode register 604 stores additional information associated with the notification-type event and/or the alert-type event.

In some implementations, the interface 602 passes information about different notification-type events using a same notification pin 122. This means that different types of notification-type events that are indicated by the event signals 612 and/or 614 are reported to the memory controller 114 in a similar manner. In other implementations, the interface 602 passes information about different notification-type events using different notification pins 122. The various events that can be reported by the event reporting circuit 126 are further described with respect to FIG. 7.

FIG. 7 illustrates example differences between notification-type events 702 and alert-type events 704. Detection of a notification-type event 702 causes the event reporting circuit 126 to notify (or more generally to report to) the memory controller 114 of the occurrence of the notification-type event 702. This notification does not interrupt normal operations of the memory controller 114 (e.g., does not interrupt normal traffic associated with write and/or read requests).

By sending a notification via the notification pin 122, the memory device 108 enables the memory controller 114 to perform a corresponding action 706 without requiring the memory controller 114 to perform the corresponding action 706. In this sense, the notification indicates to the memory controller 114 that there is an opportunity for the memory device 108 to be proactive in addressing a condition that contributed to the occurrence of the notification-type event 702. Consider an example in which the notification-type event 702 is associated with mitigating usage-based disturbance. In this example, the notification can indicate to the memory controller 114 that the memory device 108 can utilize additional resources for mitigation usage-based disturbance. However, it is not mandatory that the memory controller 114 provide these additional resources. As the memory controller 114 does not need to take immediate action based on the notification, the memory controller 114 can perform higher-priority operations and/or can perform the corresponding action 706 at a later time. In general, it is optional 708 for the memory controller 114 to perform the action 706 based on the reporting of a notification-type event 702 by the memory device 108. Depending on the notification-type event 702, the memory controller 114 may not perform the action 706 or may perform the action 706 at a later, more opportune time to reduce the impact to performance.

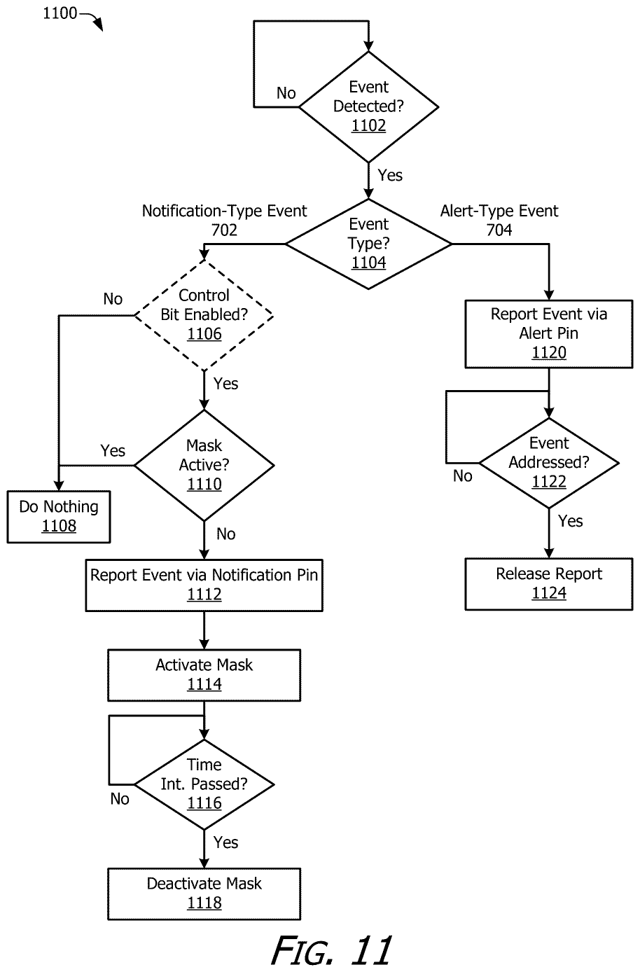

In some implementations, the event reporting circuit 126 masks 710 (e.g., blocks) the reporting of subsequent notification-type events 702 if these events 702 occur within a predetermined period of time after the event reporting circuit 126 reports an occurrence of a previous notification-type event 702. This masking procedure is further described with respect to FIG. 11. In some implementations, the memory controller 114 can set an operand within the mode register 604 to enable or disable the masking 710 of notification-type events 702.

Example notification-type events 702 include a low-risk usage-based-disturbance event 712, an array defect event 714, and a temperature-related event 716. The low-risk usage-based-disturbance event 712 indicates an occurrence of a usage-based-disturbance condition. For example, the usage-based-disturbance condition can involve a comparator of the usage-based-disturbance circuit 120 indicating that a mitigation threshold is exceeded by the activation count 308 of an activated row 302. Another usage-based-disturbance condition can involve a queue of the usage-based-disturbance circuit 120 reaching a certain quantity of entries that indicates it is partially or close to being full.

In general, the reporting of the low-risk usage-based-disturbance event 712 (or an absence of the reporting of the low-risk usage-based-disturbance event 712) provides the memory controller 114 feedback regarding how well the memory device 108 is mitigating usage-based disturbance with the currently available resources (e.g., with the current scheduling of refresh commands). As the memory device 108 reports one or more low-risk usage-based-disturbance events 712, this can indicate to the memory controller 114 that the memory device 108 requires additional resources to mitigate usage-based disturbance. Alternatively, if the memory device 108 indicates that these events are not occurring, the memory controller 114 can have increased confidence that the memory device 108 is effectively mitigating usage-based disturbance with the currently available resources. In some situations, the memory controller 114 can reduce the available resources for mitigating usage-based disturbance based on the absence of these events. In this way, the memory controller 114 can conserve power and dedicate more temporal resources to normal operations for at least a period of time.

An example array defect event 714 can include the occurrence of a defect or an indication of a potential defect within memory cells of the memory array 204. An example array defect event 714 can include detection of an error within the normal data 306 or detection of an error within the usage-based-disturbance data 214. In the case of the usage-based-disturbance data 214, the error can be determined based on the corresponding check bit 310. Example temperature-related events 716 can involve a measured temperature exceeding a threshold or being outside of a specified operation range.

The memory controller 114 can perform a variety of actions 706 based on the reporting of a notification-type event 702. The actions 706 represent different responses or reactions of the memory controller 114 to the reported notification-type event 702. Example actions 706 can include initiating a refresh operation 718, initiating a repair operation 720, and/or performing a temperature-related action 722. Although not explicitly shown in FIG. 7, another example action 706 can include reading the mode register 604 to access additional information about the notification-type event 702. This additional information can indicate if the reported notification-type event 702 corresponds to the low-risk usage-based-disturbance event 712, the array defect event 714, and/or the temperature-related event 716.

In the case that the reported notification-type event 702 is the low-risk usage-based-disturbance event 712, the memory controller 114 can optionally schedule one or more additional refresh operations 718. The refresh operation 718 can involve the memory controller 114 sending one or more refresh commands to the memory device 108. Example refresh commands can include a refresh management (RFM) command, a self-refresh command, an auto-refresh command, a normal refresh command, and/or can by any other command relating to refreshing at least one row 302 in a bank 410. The timing for performing a refresh is indicated (or controlled) by a refresh pump, which is generated by the memory device 108 based on the refresh command. The refresh pump can alternatively be referred to as a refresh pulse. The term “refresh” can also be referred to as a row refresh or a refresh operation. Generally speaking, the quantity of refresh pumps available for each refresh command can vary depending on a duration of a time interval associated with the refresh command and/or a refresh mode of the memory device 108.

Depending on the type of refresh command, some of the refresh pumps associated with the refresh command can be dedicated to normal refresh operations and thus are unavailable for mitigating usage-based disturbance. Additionally or alternatively, some or all of the refresh pumps can be available for mitigating usage-based disturbance. It is also possible that some of the refresh pumps associated with the refresh command are previously-postponed refresh pumps. To address the low-risk usage-based-disturbance event 712, the refresh command is considered to have at least one refresh pump that is available for mitigating usage-based disturbance.

If resources are constrained (e.g., the apparatus 102 is operating in a low-power mode or the memory controller 114 has higher-priority operations), the memory controller 114 may not schedule the refresh operation 718. If resources are not constrained, the memory controller 114 may schedule the refresh operation 718. In this case, the memory controller 114 can follow a defined protocol to issue additional refresh commands to assist the memory device 108 in mitigating usage-based disturbance.

In the case that the reported notification-type event 702 is the array defect event 714, the memory controller 114 can schedule one or more repair operations 720. The repair operation 720 enables the memory device 108 to repair one or more memory elements (e.g., one or more rows or columns) within the memory array 204. In various situations, memory controller 114 can schedule the repair operation 720 at a later time. In this way, the memory controller 114 does not have to interrupt current operations to perform the repair operation 720 and can wait for a suitable time. Accordingly, the repair operation 720 can be performed as part of normal operations without causing traffic to halt.

One type of repair operation 720 involves a hard post-package repair (hPPR) procedure. For the hard post-package repair procedure, the memory controller 114 can request that the memory device 108 permanently repair a whole combination row, including the faulty data used for usage-based disturbance mitigation. With this repair procedure, however, the viability of existing data stored in the memory row is uncertain. Further, the permanent, nonvolatile nature of the hard post-package repair can entail blowing a fuse. The procedure is relatively lengthy and can often be performed only during power up and initialization, or with a full memory reset, instead of in real-time while the memory device 108 is functional and performing memory operations for the host device 104.

Another type of repair operation 720 involves a soft post-package repair (sPPR), which is a temporary repair procedure that is significantly faster than the hard post-package repair. Further, although a soft post-package repair procedure produces a volatile repair, the soft post-package repair procedure can be performed in real-time responsive to detection of a failure. If a row 302 is being repaired, the computing system may be responsible, however, for handling the data transfer (e.g., a full page of data) from the row 302 corresponding to the faulty data to a spare counter and memory row combination. This data transfer can consume an appreciable amount of time while occupying the data bus.

In the case that the reported notification-type event 702 is the temperature-related event 716, the memory controller 114 can perform one or more temperature-related actions 722. Example temperature-related actions 722 can include throttling performance to reduce the temperature of the memory device 108. Another example temperature-related action 722 can include increasing a refresh rate of the memory device 108 due to a detected increase in temperature.

Detection of an alert-type event 704 causes the event reporting circuit 126 to alert (or more generally to report to) the memory controller 114 of the occurrence of the alert-type event 704. By sending an alert via the alert pin 124, the memory device 108 interrupts the normal operation of the memory controller 114 and triggers the memory controller 114 to halt normal traffic. In contrast to the optional actions 706 associated with the notification-type event 702, the memory controller 114 or the memory device 108 is required 726 to perform an action 724 that addresses the reported alert-type event 704.

In some implementations, the event reporting circuit 126 continues reporting an alert-type event 704 until the condition that triggered the event is addressed or mitigated. In this case, the reporting of the alert-type event 704 is considered to be persistent 728. For these types of reports, the termination of the report can indicate to the memory controller 114 that the reported alert-type event 704 has been addressed. In many cases, this can indicate to the memory controller 114 that normal operations can be resumed.

Example alert-type events 704 include a high-risk usage-based-disturbance event 730 and an error-related event 732. The high-risk usage-based-disturbance event 730 indicates an occurrence of an alert condition. For example, the alert condition can involve the usage-based-disturbance circuit 120 determining that an alert threshold is exceeded by the activation count 308 of the activated row 302. This indicates that the activation count 308 is approaching an intrinsic specified limitation, which is to be avoided. An occurrence of this alert condition can indicate that the usage-based-disturbance circuit 120 needs additional resources for refreshing victim rows and preventing the activation count 308 of the identified row 302 from reaching the intrinsic specified limitation. In another example, the alert condition can involve the usage-based-disturbance circuit 120 determining that its queue is full. This means that the usage-based-disturbance circuit 120 is behind in mitigation usage-based disturbance and additional refresh commands are necessary to refresh victim rows. An error-related event 732 can include detection of a command-and-address (CA) parity-check error and/or a cyclic-redundancy-check (CRC) error.

A variety of different actions 724 can be performed based on the reporting of an alert-type event 704. The actions 724 represent different responses or reactions of the memory controller 114 or the memory device 108 to the alert-type event 704. Example actions 724 can include performing an alert backoff procedure 734 and/or performing an error-correcting action 736. Although not explicitly shown in FIG. 7, another example action 724 can include the memory controller 114 reading the mode register 604 to access additional information about the alert-type event 704. This additional information can indicate if the reported alert-type event 704 corresponds to the high-risk usage-based-disturbance event 730 and/or the error-related event 732.

In the case that the reported alert-type event 704 is the high-risk usage-based-disturbance event 730, the memory device 108 performs the alert backoff procedure 734. As part of the alert backoff procedure 734, the memory device 108 pauses normal operations for a recovery period during which refresh management (RFM) commands and other functions may be performed in the memory device 108 to mitigate usage-based disturbance. During this recovery period, the memory device 108 is inaccessible to the memory controller 114 and a user while the victim rows are refreshed.

In the case that the reported alert-type event 704 is the error-related event 732, the memory controller 114 performs the error-correcting action 736. This can involve resending information over the command-and-address bus to address the command-and-address parity-check error or performing a rewrite to address the cyclic-redundancy-check error.

Although several example notification-type events 702 and alert-type events 704 are described with respect to FIG. 7, this list is not exhaustive and other events can be categorized as notification-type events 702 or alert-type events 704. An event can be considered a notification-type event 702 or an alert-type event 704 based on a risk level and/or a priority level associated with the event. The risk level represents a degree to which the memory device 108 may fail in some respects (e.g., fail to mitigate usage-based disturbance). For example, the risk level can indicate how likely the usage-based-disturbance effect will manifest a data error or how likely a row 302's activation count 308 may reach the intrinsic specified limit based on an occurrence of the event. Generally speaking, the risk level corresponds to a probability of a “worst-case” situation occurring.

The priority level indicates how important it is for the memory device 108 and/or the memory controller 114 to address the event. The priority level generally corresponds to the risk level. Events with a higher risk level can have a higher priority level, and events with a lower risk level can have a lower priority level. Some priority levels may be associated with a particular time interval. The time interval can indicate a time frame in which the memory controller 114 and/or the memory device 108 is to perform the corresponding action. Higher priority levels can have a shorter time interval while lower priority levels can have a longer time interval. Events with a lower risk and/or a lower priority can be categorized as notification-type events 702. In contrast, events with a higher risk and/or a higher priority can be categorized as alert-type events 804.

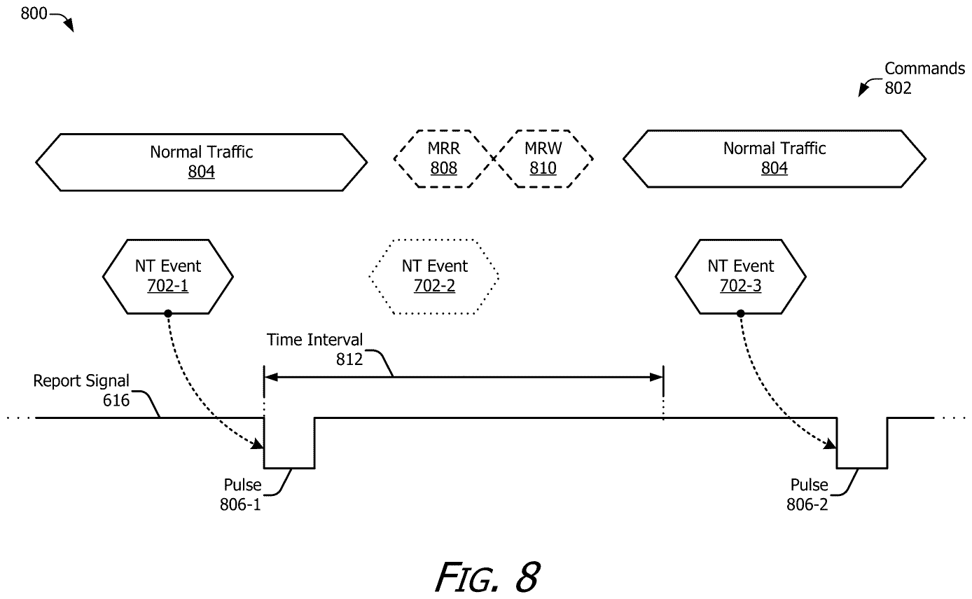

FIG. 8 illustrates an example timing diagram 800 for reporting multiple notification-type events 702. In this example, the event reporting circuit 126 generates the report signal 616 and provides the report signal 616 to the notification pin 122. The memory controller 114 sends commands 802, which include normal traffic 804. The normal traffic 804 can include normal write and/or read commands. The normal traffic 804 is associated with normal operations of the memory controller 114 and does not necessarily involve mitigating usage-based disturbance.

At some point during the normal traffic 804, a first notification-type event 702-1 occurs and is detected by the event reporting circuit 126. The event reporting circuit 126 reports the event by causing the report signal 616 to have a first pulse 806-1. A pulsewidth of the first pulse 806-1 can be sufficiently long to enable the memory controller 114 to detect the first pulse 806-1. In some implementations, a timing of the pulse 806 does not necessarily indicate a time that the first notification-type event 702-1 occurred. In other words, there can be a delay between the detecting of the first notification-type event 702-1 and the generation of the first pulse 806-1. This design choice allows the event reporting circuit 126 to have a more relaxed response time, which can simplify the cost and complexity of the event reporting circuit 126 and the notification pin 122.

After receiving the first pulse 806-1, the memory controller 114 can optionally perform an action 706. For example, the memory controller 114 can optionally send a mode register read command 808 to access information that is stored in the mode register 604 via one or more event bits. Example information can identify which notification-type event 702 was detected, the die 404 associated with the first notification-type event 702-1, and/or additional information about the first notification-type event 702-1. Additionally, the memory controller 114 can optionally send a mode register write command 810 (MRW 810) to update the information that is stored in the mode register 604. In particular, the memory controller 114 can clear the information stored by the one or more event bits so that the one or more event bits are available to capture information associated with a next notification-type event 702. In some implementations, the memory controller 114 releases the notification pin 122 to terminate the first pulse 806-1.

In this example, the event reporting circuit 126 masks the reporting of subsequent notification-type events 702 for a time interval 812. The time interval 812 represents a time it takes for the event reporting circuit 126 to generate the pulse 806-1 as well as a turn-around time it takes the event reporting circuit 126 to be available to generate a next pulse. In general, the time interval 812 is longer than the pulsewidth associated with the pulse 806. During the time interval 812, a second notification-type event 702-2 occurs and is detected by the event reporting circuit 126. However, due to a timing of the second notification-type event 702-2, the event reporting circuit 126 does not generate a pulse 806. In this case, the first pulse 806-1 can represent an occurrence of both the first notification-type event 702-1 and the second notification-type event 702-2. Information stored in the mode register 604 can indicate to the memory controller 114 the occurrence of the first and second notification-type events 702-1 and 702-2 even though one first pulse 806-1 was sent via the report signal 616.

After the time interval 812 has passed, the event reporting circuit 126 can report a next notification-type event 702. In this example, a third notification-type event 702-3 occurs after the time interval 812 and is detected by the event reporting circuit 126. The event reporting circuit 126 reports this event by generating a second pulse 806-2. The notification-type events 702-1 to 702-3 can be similar notification-type events or different notification-type events. In an example implementation, a same pulsewidth is used to indicate the occurrence of different notification-type events 702. For instance, the pulses 806-1 and 806-2 shown in FIG. 8 have a same pulsewidth. Other implementations are also possible in which the event reporting circuit 126 generates the pulses 806 to have different pulsewidths corresponding to the different types of notification-type events 702.

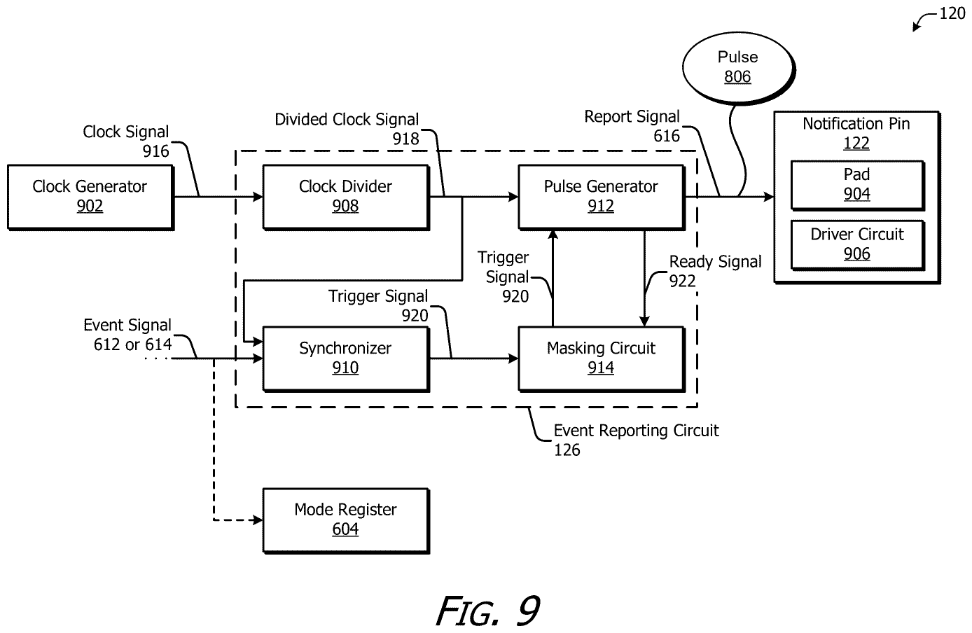

The example report signal 616 shown in FIG. 8 enables the event reporting circuit 126 to report multiple notification-type events 702 to the memory controller 114 using the notification pin 122. Although not explicitly shown in FIG. 8, the event reporting circuit 126 can also report alert-type events 704 via the alert pin 124 by generating another report signal that is different than the report signal 616 shown in FIG. 8. An example operation of the event reporting circuit 126 is further described with respect to FIG. 9.

FIG. 9. illustrates an example implementation of the event reporting circuit 126. In the depicted configuration, the event reporting circuit 126 is coupled to the notification pin 122, the mode register 604, and a clock generator 902. Although not explicitly shown in FIG. 9, the event reporting circuit 126 can also be coupled to other circuitry within the memory device 108, such as the usage-based-disturbance circuits 120 and/or the event detection circuit 606, as shown in FIG. 6.

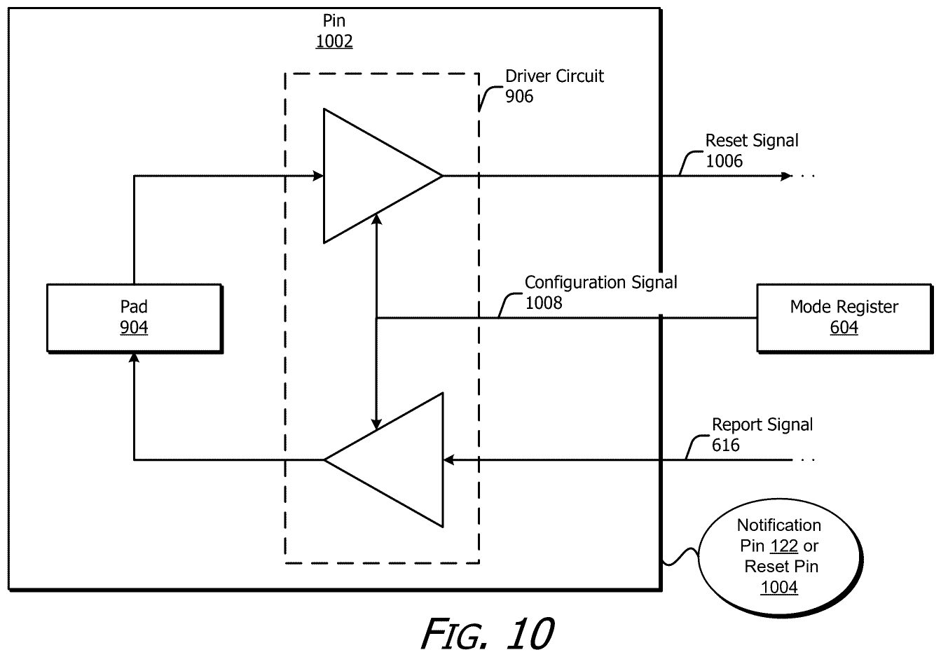

The notification pin 122 includes at least one pad 904 and at least one driver circuit 906. The pad 904 has read-out capabilities, which enables the report signal 616 to be transmitted to the memory controller 114. An example implementation of the notification pin 122 is further described with respect to FIG. 10. The event reporting circuit 126 includes at least one clock divider 908, at least one synchronizer 910, at least one pulse generator 912, and at least one masking circuit 914. The clock divider 908 enables the event reporting circuit 126 to operate at a slower speed, which can conserve power resources.

During operation, the clock generator 902 generates a clock signal 916. The clock divider 908 generates a divided clock signal 918 based on the clock signal 916. A frequency of the divided clock signal 918 is lower than a frequency of the clock signal 916. The divided clock signal 918 is passed to the pulse generator 912 and the synchronizer 910.

The event reporting circuit 126 receives the event signal 612 from the usage-based-disturbance circuit 120 and/or the event signal 614 from the event detection circuit 606. In some implementations, the event signal 612 and/or 614 sets one or more operands within the mode register 604. The synchronizer 910 generates a trigger signal 920 based on the event signal 612 or 614 and the divided clock signal 918. This enables the reporting of the notification-type event 702 that is associated with the event signal 612 or 614 to be synchronized to the clock signal 916.

The masking circuit 914 forwards the trigger signal 920 to the pulse generator 912 based on a ready signal 922 generated by the pulse generator 912. The ready signal 922 indicates if the pulse generator 912 is available to generate a next pulse. In other words, the ready signal 922 indicates whether a sufficient amount of time has elapsed (e.g., as represented by the time interval 812) since the generation of a previous pulse 806. The pulse generator 912 generates the report signal 616 based on the divided clock signal 918 and the trigger signal 920. The report signal 616 is generated with a pulse 806 and is passed to the notification pin 122. The pulse generator 912 can set the ready signal 922 to cause the masking circuit 914 to halt the forwarding of the trigger signal 920 for subsequent notification-type events 702 until a sufficient amount of time has elapsed since the generation of the pulse 806. In an example implementation, the masking circuit 914 can be implemented using an AND logic gate.

FIG. 10 illustrates an example implementation of the notification pin 122. In this example, the notification pin 122 is implemented using a pin 1002 (e.g., a multiplexed pin) that is already existing within in the memory device 108 without adding new pins to a dual in-line memory module of the memory device 108. This pin 1002 can be selectively configured to operate as the notification pin 122 or as a reset pin 1004. The mode register 604 is coupled to the driver circuit 906. The mode register 604 controls a configuration of the driver circuit 906, as further described below.

The pin 1002 operates as the reset pin 1004 by default. During a power-up procedure, the driver circuit 906 enables the pin 1002 to pass input signals that are received via the pad 904 to another component of the memory device 108. In this example, the pin 1002 can receive a reset signal 1006 at the pad 904 and pass the reset signal 1006 to other components of the memory device 108. After the power-up procedure and/or initialization, the memory controller 114 can use a mode register write command or a multi-purpose command (MPC) to cause the pin 1002 to operate as the notification pin 122. In this example, the memory controller 114 sets an operand in the mode register 604, which causes the mode register 604 to generate a configuration signal 1008. The configuration signal 1008 reconfigures the driver circuit 906 to enable the pin 1002 to pass the report signal 616 through the driver circuit 906 to the pad 904. At a later time, the memory controller 114 can reconfigure the pin 1002 as the reset pin 1004 by sending another mode register write command or another multi-purpose command.

FIG. 11 illustrates an example scheme 1100 implemented by the event reporting circuit 126 for reporting a notification-type event 702. In this example, the event reporting circuit 126 supports reporting notification-type events 702 and alert-type events 704. An example notification-type event 702 can be associated with usage-based-disturbance mitigation. In some implementations, the event reporting circuit 126 also supports reporting notification-type events 702 associated with normal operations (e.g., operations that do not involve mitigating usage-based disturbance). An alert-type event 704 can be associated with usage-based-disturbance mitigation or normal operations.

At 1102, the event reporting circuit 126 determines if an event is detected. For example, the event reporting circuit 126 analyzes the event signals 612 to determine if a notification-type event 702 and/or an alert-type event 704 is detected by the usage-based-disturbance circuits 120. Optionally, the event reporting circuit 126 can also analyze the event signal 614 to determine if a notification-type event 702 and/or an alert-type event 704 is detected by the event detection circuit 606.

At 1104, the event reporting circuit 126 determines the type of event that is detected. If the event corresponds to a notification-type event 702, the event reporting circuit 126 can optionally determine if a control bit corresponding to the notification-type event 702 is enabled within the mode register 604. If the control bit is not enabled, the event reporting circuit 126 does nothing at 1008. Otherwise, if the control bit is enabled, the process continues to 1110.

At 1110, the event reporting circuit 126 determines if a mask 710 is active. A mask 710 can be active if the event reporting circuit 126 reported a previous notification-type event 702 and activated the mask 710. When the mask 710 is active, the event reporting circuit 126 does not report another notification-type event 702. As such, the event reporting circuit 126 does nothing at 1108. If the mask 710 is not active at 1110, the process continues to 1112.

At 1112, the event reporting circuit 126 reports the notification-type event 702 via the notification pin 122. For example, the event reporting circuit 126 can report the event by generating the report signal 616 and passing the report signal 616 to the notification pin 122, as shown in FIG. 9. The event reporting circuit 126 also activates the mask 710 at 1114 to prevent other notification-type events 702 from being reported for a predetermined time interval (e.g., for the time interval 812). While the mask 710 is active, the event reporting circuit 126 skips (e.g., omits or refrains from) the reporting of notification-type events 802. The mask 710 does not impact the reporting of alert-type events 804.

At 1116, the event reporting circuit 126 monitors whether the time interval has passed. If the amount of time between the occurrences of two notification-type events 702 exceeds the predetermined time interval (e.g., exceeds a threshold), the event reporting circuit 126 deactivates the mask 710 at 1118. This allows the next notification-type event 702 to be reported. If the predetermined time interval has not passed since the reporting of the notification-type event 702 at 1112, the mask 710 remains active and prevents the event reporting circuit 126 from reporting additional notification-type events 702.

Returning to 1104, if the detected event is an alert-type event 704, the event reporting circuit 126 reports the alert-type event 704 via the alert pin 124 at 1120. For example, the event reporting circuit 126 can report the alert-type event 704 by generating another report signal 616 and passing this report signal 616 to the alert pin 124.

In some implementations, the event reporting circuit 126 persistently reports the alert-type event 704. This can involve generating the report signal 616 with a persistent pulse. At 1122, the event reporting circuit 126 monitors if the alert-type event 704 (e.g., the condition that triggered the event) has been addressed. In the case of the high-risk usage-based-disturbance event 730, this can include determining that victim rows corresponding to the row 302 with the activation count 308 that exceeded the alert threshold have been refreshed. In another example of the high-risk usage-based-disturbance event 730, this can include determining that the queue has some empty space for new entries. Once the alert-type event 704 has been addressed, the event reporting circuit 126 releases the report at 1124. In other words, the event reporting circuit 126 stops reporting the event (e.g., terminates the pulse of the report signal 616). By releasing the report, the memory device 108 is effectively reporting to the memory controller 114 that the condition that triggered the alert-type event 704 has been addressed. This enables the memory controller 114 to resume normal operations.

### Example Methods

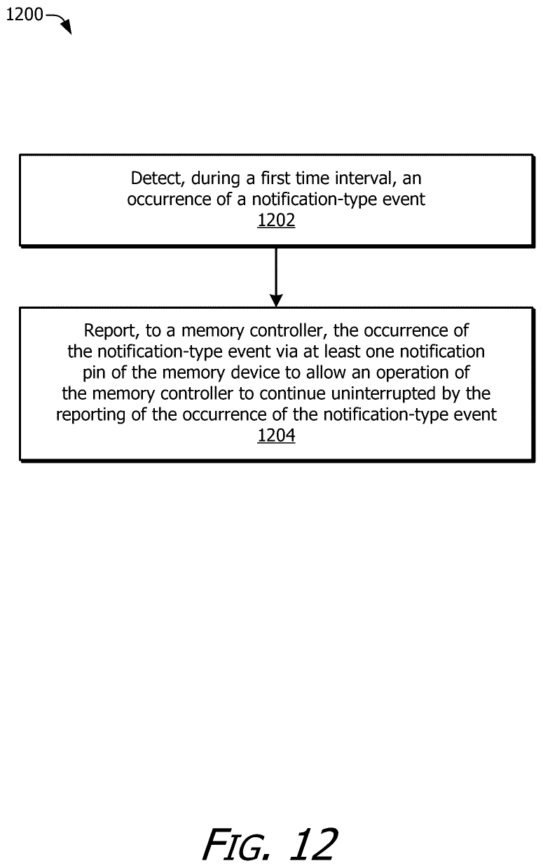

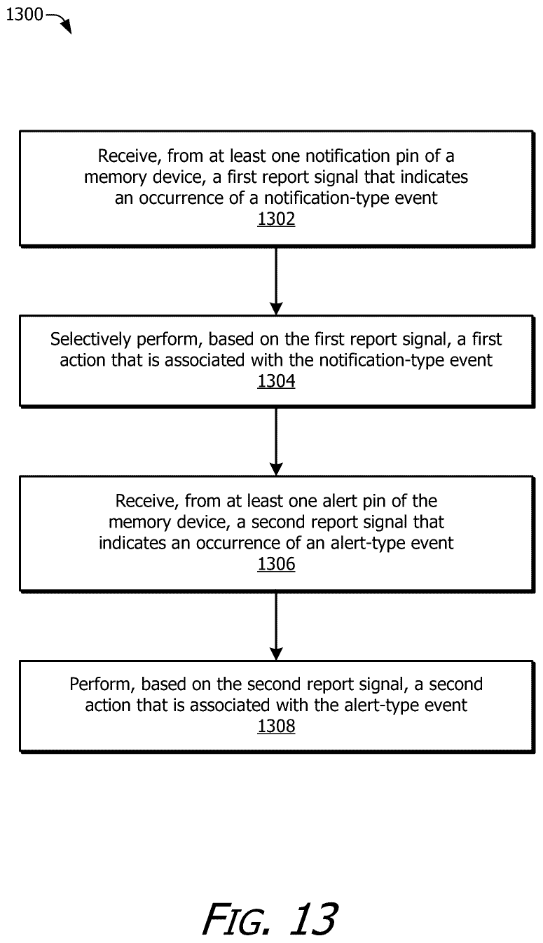

This section describes example methods for implementing aspects of reporting a notification-type event with reference to the flow diagrams of FIGS. 12 and 13. This description may also refer to components, entities, and other aspects depicted in FIGS. 1 to 11 by way of example only. The described methods are not necessarily limited to performance by one entity or multiple entities operating on one device.

FIG. 12 illustrates a method 1200, which includes operations 1202 through 1204. In aspects, operations of the method 1200 are implemented by a memory device 108 as described with reference to FIG. 1. In particular, the operations of the method 1200 are performed, at least in part, by the event reporting circuit 126 of FIG. 1.

At 1202, an occurrence of a notification-type event is detected during a first time interval. For example, the event reporting circuit 126 detects an occurrence of a notification-type event 702 during a first time interval. In an example implementation, the event reporting circuit 126 indirectly detects the occurrence of the notification-type event 702 based on event signals 612 provided by one or more usage-based-disturbance circuits 120 and/or based on the event signal 614 provided by the event detection circuit 606, as shown in FIG. 6. Other implementations are also possible in which the event reporting circuit 126 includes logic capable of directly detecting one or more notification-type events 702. Some notification-type events 702 can be associated with usage-based-disturbance mitigation while other notification-type events 702 can be associated with normal operations (e.g., other operations that do not involve mitigating usage-based disturbance). Example notification-type events 702 can include the low-risk usage-based-disturbance event 712, the array defect event 714, and/or the temperature-related event 716, as shown in FIG. 7.

At 1204, the occurrence of the notification-type event is reported to the memory controller via at least one notification pin of the memory device to allow an operation of the memory controller to continue uninterrupted by the reporting of the occurrence of the notification-type event. For example, the event reporting circuit 126 reports, to the memory controller 114, the occurrence of the notification-type event 702 via the at least one notification pin 122. This allows an operation of the memory controller 114 to continue uninterrupted by the reporting of the occurrence of the notification-type event 702. The memory controller 114 is not obligated to react immediately to the reporting of a notification-type event 702. Instead, the memory controller 114 can decide to take action based on the reporting of the notification-type event 702 at a later time to reduce performance impact. The event reporting circuit 126 can also write information to an operand of the mode register 604 to pass along additional information associated with the notification-type event 702 to the memory controller 114. In this situation, the memory controller 114 can read the mode register 604 to obtain the additional information and use this additional information to determine if and/or when it will perform the first action 706.

The reporting of the notification-type event 702 can be dependent on a configuration of a control bit that is stored by the mode register 604. If the control bit for the detected notification-type event 702 is enabled, the event reporting circuit 126 can report the occurrence of the notification-type event 702, as described at 1112 in FIG. 11. Otherwise, if the control bit for the detected notification-type event 702 is disabled, the event reporting circuit 126 skips reporting the occurrence of the notification-type event 702, as indicated at 1108 in FIG. 11. By setting the appropriate control bit, the memory controller 114 can dynamically customize which notification-type events 702 can be reported by the memory device 108.

In some implementations, the event reporting circuit 126 can also report alert-type events 704 to the memory controller 114 using at least one alert pin 124. By reporting notification-type events 702 and alert-type events 704 via different pins 122 and 124, the memory device 108 can make it easier for the memory controller 114 to take appropriate action and efficiently manage available resources in a power-efficient and performance-preserving manner.

FIG. 13 illustrates a method 1300, which includes operations 1302 through 1308. In aspects, operations of the method 1300 are implemented by a host device 104 as described with reference to FIG. 1. In particular, the operations of the method 1300 are performed by the memory controller 114 of FIG. 1.

At 1302, a first report signal that indicates an occurrence of a notification-type event is received from at least one notification pin of a memory device. For example, the memory controller 114 receives, from at least one notification pin 122 of the memory device 108, a first report signal 616 that indicates an occurrence of a notification-type event 702. The notification-type event 702 can be associated with usage-based-disturbance mitigation or can be associated with normal operations (e.g., an operation that does not involve mitigating usage-based disturbance). Example notification-type events 702 can include the low-risk usage-based-disturbance event 712, the array defect event 714, and/or the temperature-related event 716, as shown in FIG. 7.

At 1304, a first action that is associated with the notification-type event is selectively performed based on the first report signal. For example, the memory controller 114 selectively performs, based on the first report signal 616, a first action 706 that is associated with the reported notification-type event 702. Example actions 706 can include initiating a refresh operation 718, initiating a repair operation 720, and/or performing a temperature-related action 722, as described in FIG. 7.

At 1306, a second report signal that indicates an occurrence of an alert-type event is received from at least one alert pin of the memory device. For example, the memory controller 114 receives, from at least one alert pin 124 of the memory device 108, a second report signal 616 that indicates an occurrence of an alert-type event 704. The alert-type event 704 can be associated with usage-based-disturbance mitigation or can be associated with normal operations (e.g., an operation that does not involve mitigating usage-based disturbance). Example alert-type events 704 can include a high-risk usage-based-disturbance event 730 or an error-related event 732, as shown in FIG. 7.

At 1308, a second action that is associated with the alert-type event is performed based on the second report signal. For example, the memory controller 114 can halt normal operations (e.g., halt normal traffic 804) based on the second report signal 616. In some situations, the memory controller 114 performs a second action 724 that is associated with the alert-type event 704, such as the error-correcting action 736. In other situations, the memory device 108 performs a second action 724 that is associated with the alert-type event 704, such as the alert backoff procedure 734.

Aspects of the above methods may be implemented in, for example, hardware (e.g., fixed-circuit circuitry or a processor in conjunction with a memory), firmware, software, or some combination thereof. The methods may be realized using one or more of the apparatuses or components shown in FIGS. 1 to 11, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media includes both non-transitory computer storage media and communication media including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

In the following, various examples for implementing aspects of reporting a notification-type event are described:
Example 1: A method performed by a memory device that is coupled to a memory controller, the method comprising:
   detecting, during a first time interval, an occurrence of a notification-type event; and
   reporting, to the memory controller, the occurrence of the notification-type event via at least one notification pin of the memory device to allow an operation of the memory controller to continue uninterrupted by the reporting of the occurrence of the notification-type event.
Example 2: The method of example 1 or any other example, wherein the reporting of the occurrence of the notification-type event enables the memory controller to selectively perform a first action associated with the notification-type event or skip performing the first action.
Example 3: The method of example 1 or any other example, wherein the notification-type event is associated with mitigating usage-based disturbance.
Example 4: The method of example 1 or any other example, further comprising:
   detecting, during a second time interval, an occurrence of an alert-type event; and
   reporting, to the memory controller, the occurrence of the alert-type event via at least one alert pin of the memory device to cause the memory controller to perform a second action associated with the alert-type event.
Example 5: The method of example 4 or any other example, wherein:
   the reporting of the occurrence of the notification-type event comprises notifying the memory controller of the occurrence of the notification-type event without interrupting the operation of the memory controller; and
   the reporting of the occurrence of the alert-type event comprises alerting the memory controller to the occurrence of the alert-type event and interrupting the operation of the memory controller.
Example 6: The method of example 4 or any other example, wherein:
   the detecting of the occurrence of the notification-type event comprises at least one of the following:
      determining that an activation count of a row is greater than a mitigation threshold associated with mitigating usage-based disturbance within a memory array of the memory device;
      detecting a defect in the memory array; or
      determining that a temperature associated with a die of the memory device is greater than a threshold or is outside of specified range; and
   the detecting of the occurrence of the alert-type event comprises at least one of the following:
      determining that the activation count of the row is greater than an alert threshold associated with mitigating usage-based disturbance, the alert threshold being greater than the mitigation threshold;
      determining that a queue storing addresses of aggressor rows is full;
      detecting a command-and-address parity-check error; or
      detecting a cyclic-redundancy-check error.
Example 7: The method of example 1 or any other example, further comprising:
   detecting, during a third time interval, an occurrence of a second notification-type event associated with normal operations; and
   reporting, to the memory controller, the occurrence of the second notification-type event via the at least one notification pin to allow the operation of the memory controller to continue uninterrupted.
Example 8: The method of example 7 or any other example, wherein:
   the reporting of the occurrence of the notification-type event comprises setting at least one first operand of at least one mode register of the memory device; and
   the reporting of the occurrence of the second notification-type event comprises setting at least one second operand of the at least one mode register of the memory device.
Example 9: The method of example 7 or any other example, wherein:
   the reporting of the occurrence of the notification-type event comprises:
      generating a report signal with a first pulse; and
      providing the report signal to the at least one notification pin;
   the third time interval occurs after a time interval associated with the generation of the first pulse; and
   the reporting of the occurrence of the second notification-type event comprises:
      generating the report signal with a second pulse that occurs after the first pulse; and
      providing the report signal to the at least one notification pin.
Example 10: The method of example 7 or any other example, wherein:
   the reporting of the occurrence of the notification-type event comprises:
      generating a report signal with a first pulse; and
      providing the report signal to the at least one notification pin;
   the third time interval occurs during at least some portion of a time interval associated with the generation of the first pulse; and
   the reporting of the occurrence of the second notification-type event comprises:
      refraining from generating the report signal with a second pulse such that the first pulse represents the occurrences of the notification-type event and the second notification-type event.
Example 11: The method of example 1 or any other example, further comprising:
   storing, in an operand of a mode register of the memory device, a control bit for selectively enabling or disabling reporting of a third notification-type event;
   detecting, during a fourth time interval, an occurrence of the third notification-type event; and
   selectively:
      reporting, to the memory controller, the occurrence of the third notification-type event via the at least one notification pin based on the operand indicating that the reporting of the third notification-type event is enabled; or
      refraining from the reporting of the occurrence of the third notification-type event based on the operand indicating that the reporting of the third notification-type event is disabled.
Example 12: A memory device comprising:
   at least one notification pin configured to be coupled to a memory controller; and
   at least one circuit coupled to the at least one notification pin and configured to:
      detect, during a first time interval, an occurrence of a notification-type event; and
      report, to the memory controller, the occurrence of the notification-type event via the at least one notification pin to allow an operation of the memory controller to continue uninterrupted by the reporting of the occurrence of the notification-type event.
Example 13: The memory device of example 12 or any other example, further comprising:
   at least one alert pin configured to be coupled to the memory controller,
   wherein the at least one circuit is coupled to the at least one alert pin and is configured to:
      detect, during a second time interval, an occurrence of an alert-type event; and
      report, to the memory controller, the occurrence of the alert-type event via the at least one alert pin to interrupt the operation of the memory controller with the reporting of the occurrence of the alert-type event.
Example 14: The memory device of example 13 or any other example, wherein the at least one notification pin and the at least one alert pin have a same configuration.
Example 15: The memory device of example 12 or any other example, wherein the at least one circuit is configured to:
   generate a report signal with a first pulse based on the detection of the notification-type event;
   detect, during a third time interval, an occurrence of a second notification-type event;
   based on the detection of the second notification-type event, selectively:
      generate the report signal with a second pulse that occurs after the first pulse based on the third time interval occurring after a time interval associated with the generation of the first pulse; or
      refrain from the generation of the second pulse based on the third time interval occurring during at least some portion of the time interval associated with the generation of the first pulse; and
   pass the report signal to the at least one notification pin to report the occurrence of the notification-type event and the second notification-type event.
Example 16: The memory device of example 12 or any other example, further comprising:
   at least one mode register configured to store one or more control bits for selecting enabling or disabling or reporting of one or more notification-type events,
   wherein the at least one circuit is further configured to report the occurrence of the notification-type event based on the at least one mode register having a control bit of the one or more control bits indicating that reporting of the one or more notification-type events is enabled.
Example 17: A method performed by a memory controller that is coupled to a memory device, the method comprising:
   receiving, from at least one notification pin of the memory device, a first report signal that indicates an occurrence of a notification-type event;
   selectively performing, based on the first report signal, a first action that is associated with the notification-type event;
   receiving, from at least one alert pin of the memory device, a second report signal that indicates an occurrence of an alert-type event; and
   performing, based on the second report signal, a second action that is associated with the alert-type event.
Example 18: The method of example 17 or any other example, wherein:
   the receiving of the first report signal does not interrupt an operation of the memory controller; and
   the receiving of the second report signal interrupts the operation of the memory controller.
Example 19: The method of example 17 or any other example, further comprising:
   prior to receiving the first report signal, setting a control bit of a mode register of the memory device to enable reporting of the notification-type event.
Example 20: The method of example 17 or any other example, wherein the receiving of the first report signal comprises:
   receiving, from the at least one notification pin of the memory device and during a first time interval, the first report signal having a first pulse that indicates the occurrence of the notification-type event; and
   receiving, from the at least one notification pin and during a second time interval, the first report signal having a second pulse that indicates an occurrence of a second notification-type event, at least one of the notification-type event or the second notification-type event associated with mitigating usage-based disturbance within a memory array of the memory device.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### Conclusion

Although aspects of reporting a notification-type event have been described in language specific to certain features and/or methods, the subject of the appended claims is not necessarily limited to the specific features or methods described. Rather, the specific features and methods are disclosed as a variety of example implementations of reporting a notification-type event.

What is claimed is:

1. A method performed by a memory device that is coupled to a memory controller, the method comprising:
detecting, during a first time interval, an occurrence of a notification-type event; and
reporting, to the memory controller, the occurrence of the notification-type event via at least one notification pin of the memory device to allow an operation of the memory controller to continue uninterrupted by the reporting of the occurrence of the notification-type event.

2. The method of claim 1, wherein the reporting of the occurrence of the notification-type event enables the memory controller to selectively perform a first action associated with the notification-type event or skip performing the first action.

3. The method of claim 1, wherein the notification-type event is associated with mitigating usage-based disturbance.

4. The method of claim 1, further comprising:
detecting, during a second time interval, an occurrence of an alert-type event; and
reporting, to the memory controller, the occurrence of the alert-type event via at least one alert pin of the memory device to cause the memory controller to perform a second action associated with the alert-type event.

5. The method of claim 4, wherein:
the reporting of the occurrence of the notification-type event comprises notifying the memory controller of the occurrence of the notification-type event without interrupting the operation of the memory controller; and
the reporting of the occurrence of the alert-type event comprises alerting the memory controller to the occurrence of the alert-type event and interrupting the operation of the memory controller.

6. The method of claim 4, wherein:
the detecting of the occurrence of the notification-type event comprises at least one of the following:
determining that an activation count of a row is greater than a mitigation threshold associated with mitigating usage-based disturbance within a memory array of the memory device;
detecting a defect in the memory array; or
determining that a temperature associated with a die of the memory device is greater than a threshold or is outside of specified range; and
the detecting of the occurrence of the alert-type event comprises at least one of the following:
determining that the activation count of the row is greater than an alert threshold associated with mitigating usage-based disturbance, the alert threshold being greater than the mitigation threshold;
determining that a queue storing addresses of aggressor rows is full;
detecting a command-and-address parity-check error; or
detecting a cyclic-redundancy-check error.

7. The method of claim 1, further comprising:
detecting, during a third time interval, an occurrence of a second notification-type event associated with normal operations; and
reporting, to the memory controller, the occurrence of the second notification-type event via the at least one notification pin to allow the operation of the memory controller to continue uninterrupted.

8. The method of claim 7, wherein:
the reporting of the occurrence of the notification-type event comprises setting at least one first operand of at least one mode register of the memory device; and
the reporting of the occurrence of the second notification-type event comprises setting at least one second operand of the at least one mode register of the memory device.

9. The method of claim 7, wherein:
the reporting of the occurrence of the notification-type event comprises:
generating a report signal with a first pulse; and
providing the report signal to the at least one notification pin;
the third time interval occurs after a time interval associated with the generation of the first pulse; and
the reporting of the occurrence of the second notification-type event comprises:
generating the report signal with a second pulse that occurs after the first pulse; and
providing the report signal to the at least one notification pin.

10. The method of claim 7, wherein:
the reporting of the occurrence of the notification-type event comprises:
generating a report signal with a first pulse; and
providing the report signal to the at least one notification pin;
the third time interval occurs during at least some portion of a time interval associated with the generation of the first pulse; and
the reporting of the occurrence of the second notification-type event comprises:
refraining from generating the report signal with a second pulse such that the first pulse represents the occurrences of the notification-type event and the second notification-type event.

11. The method of claim 1, further comprising:
storing, in an operand of a mode register of the memory device, a control bit for selectively enabling or disabling reporting of a third notification-type event;
detecting, during a fourth time interval, an occurrence of the third notification-type event; and
selectively:
reporting, to the memory controller and via the at least one notification pin, the occurrence of the third notification-type event based on the operand indicating that the reporting of the third notification-type event is enabled; or
refraining from the reporting of the occurrence of the third notification-type event based on the operand indicating that the reporting of the third notification-type event is disabled.

12. A memory device comprising:
at least one notification pin configured to be coupled to a memory controller; and
at least one circuit coupled to the at least one notification pin and configured to:
detect, during a first time interval, an occurrence of a notification-type event; and
report, to the memory controller, the occurrence of the notification-type event via the at least one notification pin to allow an operation of the memory controller to continue uninterrupted by the reporting of the occurrence of the notification-type event.

13. The memory device of claim 12, further comprising:
at least one alert pin configured to be coupled to the memory controller,
wherein the at least one circuit is coupled to the at least one alert pin and is configured to:
detect, during a second time interval, an occurrence of an alert-type event; and
report, to the memory controller, the occurrence of the alert-type event via the at least one alert pin to interrupt the operation of the memory controller with the reporting of the occurrence of the alert-type event.

14. The memory device of claim 13, wherein the at least one notification pin and the at least one alert pin have a same configuration.

15. The memory device of claim 12, wherein the at least one circuit is configured to:
generate a report signal with a first pulse based on the detection of the notification-type event;
detect, during a third time interval, an occurrence of a second notification-type event;
based on the detection of the second notification-type event, selectively:
generate the report signal with a second pulse that occurs after the first pulse based on the third time interval occurring after a time interval associated with the generation of the first pulse; or
refrain from the generation of the second pulse based on the third time interval occurring during at least some portion of the time interval associated with the generation of the first pulse; and
pass the report signal to the at least one notification pin to report the occurrence of the notification-type event and the second notification-type event.

16. The memory device of claim 12, further comprising:
at least one mode register configured to store one or more control bits for selecting enabling or disabling of reporting of one or more notification-type events,
wherein the at least one circuit is further configured to report the occurrence of the notification-type event based on the at least one mode register having a control bit of the one or more control bits indicating that reporting of the one or more notification-type events is enabled.

17. A method performed by a memory controller that is coupled to a memory device, the method comprising:
receiving, from at least one notification pin of the memory device, a first report signal that indicates an occurrence of a notification-type event;
selectively performing, based on the first report signal, a first action that is associated with the notification-type event;
receiving, from at least one alert pin of the memory device, a second report signal that indicates an occurrence of an alert-type event; and
performing, based on the second report signal, a second action that is associated with the alert-type event.

18. The method of claim 17, wherein:
the receiving of the first report signal via the at least one notification pin does not interrupt an operation of the memory controller; and
the receiving of the second report signal via the at least one alert pin interrupts the operation of the memory controller.

19. The method of claim 17, further comprising:
prior to receiving the first report signal, setting a control bit of a mode register of the memory device to enable reporting of the notification-type event.

20. The method of claim 17, wherein the receiving of the first report signal comprises:
receiving, from the at least one notification pin of the memory device and during a first time interval, the first report signal having a first pulse that indicates the occurrence of the notification-type event; and
receiving, from the at least one notification pin and during a second time interval, the first report signal having a second pulse that indicates an occurrence of a second notification-type event, at least one of the notification-type event or the second notification-type event associated with mitigating usage-based disturbance within a memory array of the memory device.
